(19) United States
(12) Patent Application Publication
(10) Pub. No.: US 2019/0324909 A1
(43) Pub. Date: Oct. 24, 2019

(54) INFORMATION PROCESSING APPARATUS AND INFORMATION PROCESSING METHOD

(71) Applicant: FUJITSU LIMITED, Kawasaki-shi (JP)

(72) Inventor: Takumi Honda, Kawasaki (JP)

(73) Assignee: FUJITSU LIMITED, Kawasaki-shi (JP)

(21) Appl. No.: 16/366,459

(22) Filed: Mar. 27, 2019

(30) Foreign Application Priority Data
Apr. 19, 2018 (JP) 2018-080924

(51) Int. Cl. G06F 12/0815; G01R 29/08; G01R 33/10

(52) U.S. Cl. CPC G06F 12/0815; G06F 2212/608; G01R 33/10; G01R 29/0892

(57) ABSTRACT

An information processing apparatus that performs a process of an N-dimensional FDTD method, the information processing apparatus includes a memory; and a processor coupled to the memory and configured to: update a cell in a +1 direction of a predetermined coordinate of an N-dimension, store an updated value in a cache memory, and after storing the updated value, update the cell of the predetermined coordinate using the updated value stored in the cache memory.

### CROSS-REFERENCE TO RELATED APPLICATION

This application is based upon and claims the benefit of the prior Japanese Patent Application No. 2018-080924, filed on Apr. 19, 2018, the entire contents of which are incorporated herein by reference.

### FIELD

The embodiments discussed herein are related to an information processing apparatus, an information processing method, and an information processing program.

### BACKGROUND

A finite-difference time-domain (FDTD) method, which is used for the analysis and simulation of electromagnetic fields, is a method of calculating electric fields and magnetic fields by dividing a space into cells in a lattice form and solving the Maxwell equations with respect to time and space by a differential method. In the FDTD method, a calculation is performed using a computer. Recent computers have a hierarchical memory structure in which a high-speed small capacity memory and a low-speed large capacity memory are combined as in, for example, a cache memory and a main memory. Meanwhile, in the FDTD method, the data at the previous time stored in the main memory is used to alternately update the electric fields and the magnetic fields every time.

Related technologies are disclosed in, for example, Japanese Laid-open Patent Publication Nos. 2006-139723 and 2009-245057.

### SUMMARY

According to an aspect of the embodiments, an information processing apparatus that performs a process of an N-dimensional FDTD method, the information processing apparatus includes a memory; and a processor coupled to the memory and configured to: update a cell in a +1 direction of a predetermined coordinate of an N-dimension, store an updated value in a cache memory, and after storing the updated value, update the cell of the predetermined coordinate using the updated value stored in the cache memory.

The object and advantages of the invention will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 a block diagram illustrating an example of a configuration of an information processing apparatus according to a first embodiment;

FIG. 2 is a diagram illustrating an example of a one-dimensional FDTD method;

FIG. 3 is a diagram illustrating an example of a relationship between an electric field and a magnetic field in a one-dimensional FDTD method;

FIG. 4 is a diagram illustrating an example of a two-dimensional FDTD method;

FIG. 5 is a diagram illustrating an example of a relationship between an electric field and a magnetic field in the two-dimensional FDTD method;

FIG. 6 is a diagram illustrating an example of a code when updating a magnetic field after updating an electric field;

FIG. 7 is a diagram illustrating an example of a hierarchical memory architecture;

FIG. 8 is a diagram illustrating an example of a constraint of an update order;

FIG. 9 is a diagram illustrating an example of a pattern of a cell update order;

FIG. 10 is a diagram illustrating an example of a combination of patterns of the cell update order;

FIG. 11 is a diagram illustrating an example of a transition of a memory state when updating a magnetic field after updating an electric field;

FIG. 12 is a diagram illustrating an example of a transition of a memory state when updating an electric field and a magnetic field for each cell of interest;

FIG. 13 is a diagram illustrating an example of a code when updating an electric field and a magnetic field for each cell of interest;

FIG. 14 is a flowchart illustrating an example of an updating process according to the first embodiment;

FIG. 15 is a block diagram illustrating an example of a configuration of an information processing apparatus according to a second embodiment;

FIG. 16 is a diagram illustrating an example of a configuration of a GPU;

FIG. 17 is a diagram illustrating an example of a case of updating a magnetic field after updating an electric field in the GPU.

FIG. 18 is a diagram illustrating an example of a transition of a memory state in an updating process;

FIG. 19 is a diagram illustrating an example of a transition of a memory state in an updating process;

FIG. 20 is a diagram illustrating an example of a transition of a memory state in an updating process;

FIG. 21 is a diagram illustrating an example of a transition of a memory state in an updating process;

FIG. 22 is a diagram illustrating an example of a transition of a memory state in an updating process;

FIG. 23 is a diagram illustrating an example of a transition of a memory state in an updating process;

FIG. 24 is a diagram illustrating an example of a transition of a memory state in an updating process;

FIG. 25 is a diagram illustrating an example of a transition of a memory state in an updating process;

FIG. 26 is a diagram illustrating an example of a transition of a memory state in an updating process;

FIG. 27 is a diagram illustrating an example of a transition of a memory state in an updating process;

FIG. 28 is a diagram illustrating an example of performance evaluation in a three-dimensional FDTD method;

FIG. 29 is a flowchart illustrating an example of an updating process according to the second embodiment;

FIG. 30 is a flowchart illustrating an example of a process of updating E and H; and

FIG. 31 is a diagram illustrating an example of a computer that executes an information processing program.

### DESCRIPTION OF EMBODIMENTS

In the FDTD method, since there are many times of reading data and recording update data at the previous time, memory access becomes a bottleneck. Especially, in a hierarchical memory structure, when the data of the previous time stored in the low-speed main memory is used, the access delay increases, which hinders speeding up a process.

Embodiments of an information processing apparatus and an information processing method described in the present disclosure will be described in detail below with reference to the accompanying drawings. Here, the disclosed technology is not limited by the embodiments. In addition, the embodiments may be appropriately combined with each other within a range that does not cause any inconsistency.

### First Embodiment

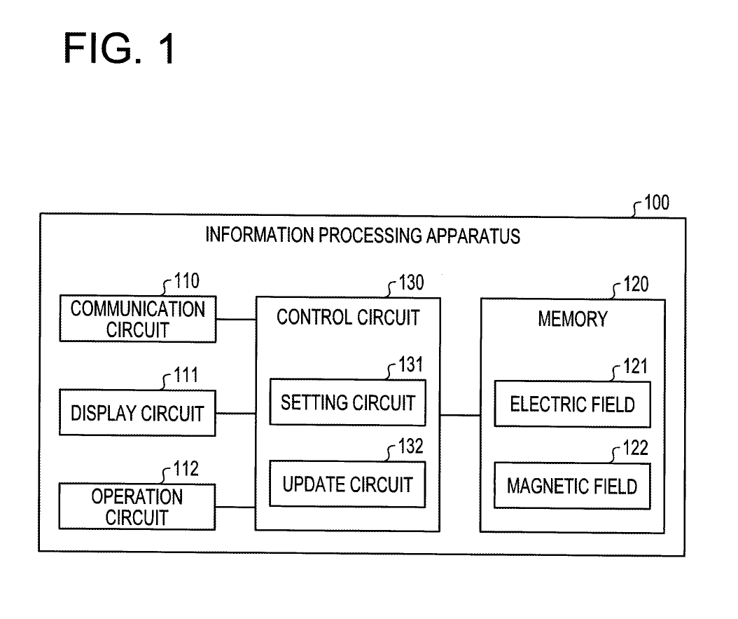

FIG. 1 a block diagram illustrating an example of a configuration of an information processing apparatus according to a first embodiment. The information processing apparatus 100 illustrated in FIG. 1 is an example of an information processing apparatus that performs a process of an N-dimensional FDTD method. The information processing apparatus 100 updates cells in the +1 direction of predetermined coordinates of N dimensions, stores the updated values in the cache memory, and then, updates cells of the predetermined coordinates using the stored values. As a result, the information processing apparatus 100 may reduce the number of memory accesses at the time of updating in the FDTD method. In the following description, a cell may also be expressed as an element.

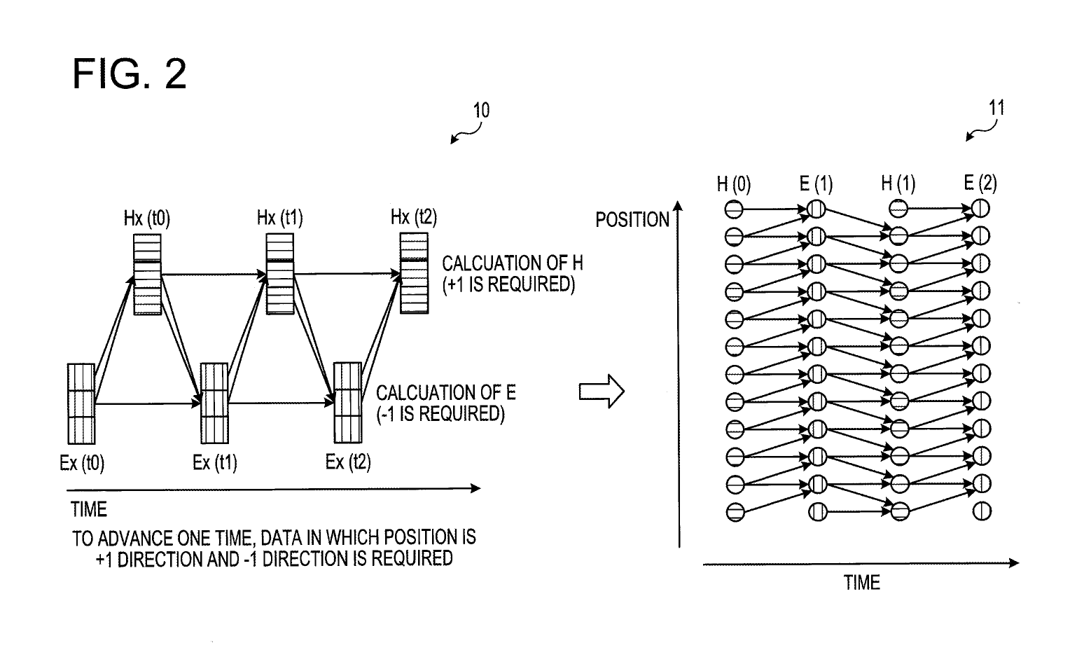

First, calculation of an electric field and a magnetic field in the FDTD method will be described with reference to FIGS. 2 to 6. FIG. 2 is a diagram illustrating an example of a one-dimensional FDTD method. As illustrated in the calculation order 10 of FIG. 2, in order to calculate an electric field Ex (t1) in the one-dimensional FDTD method, an electric field Ex (t0) and a magnetic field Hx (t0) in which the time at the same position is one step before, and the magnetic field Hx (t0) in which the time is one step before and the position is in the −1 direction are required. Also, in order to calculate the magnetic field Hx (t1), the magnetic field Hx (t0) which is one step before the same position and the electric field Ex (t1) with the same position and the position in the +1 direction are required. This relationship may be schematically illustrated in a graph 11.

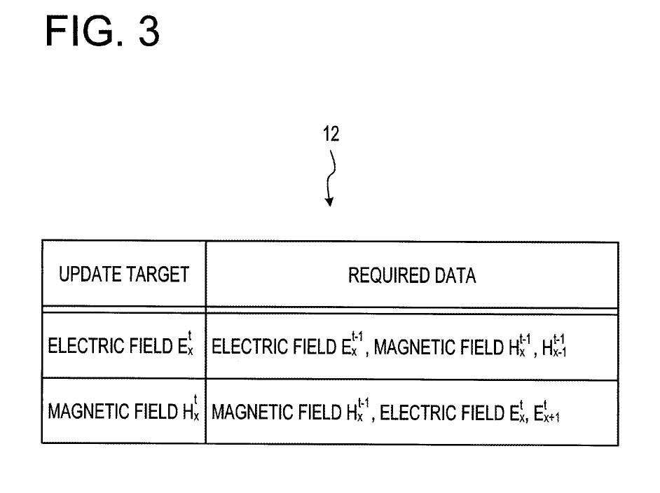

FIG. 3 is a diagram illustrating an example of a relationship between an electric field and a magnetic field in a one-dimensional FDTD method. Table 12 illustrated in FIG. 3 is a table in which update targets in the one-dimensional FDTD method are associated with necessary data. In Table 12, when the position is represented by x and the time is represented by t, and when the update target is the electric field E at position x and time t, the electric field E and the magnetic field H at position x and time t−1, and the magnetic field H at position x−1 and time t−1 are required. In addition, in Table 12, when the update target is the magnetic field H at position x and time t, the magnetic field H at position x and time t−1, the electric field E at position x and time t, and the electric field E at position x+1 and time t are required.

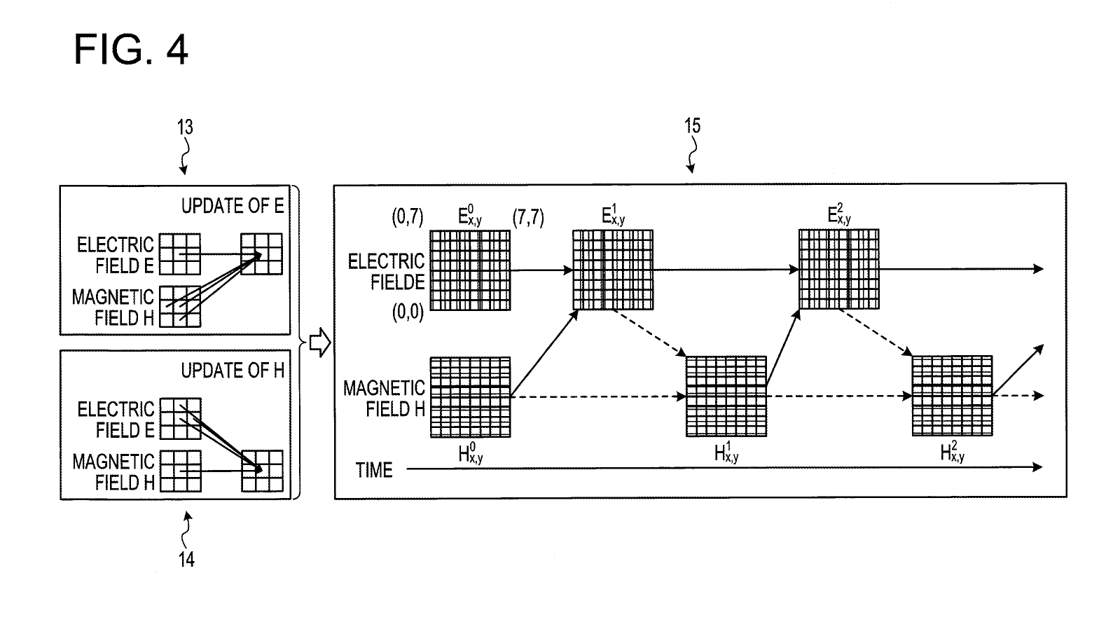

FIG. 4 is a diagram illustrating an example of a two-dimensional FDTD method. As illustrated in a dependence relationship 13 of FIG. 4, in the two-dimensional FDTD method, in order to calculate the electric field E, the electric field E and the magnetic field H in which the time at the same position are one step before, and the magnetic field H in which the time in the −1 direction on the x axis and the y axis, respectively, is one step before are required. Further, as illustrated in a dependence relationship 14, in order to calculate the magnetic field H, the magnetic field H in which the time at the same position is one step before, and the electric field E in the +1 direction of the x axis and the y axis, respectively, are required. The calculation order 15 schematically illustrates a case where the dependence relationships 13 and 14 are applied to the areas of coordinates (0, 0) to (7, 7). In the calculation order 15, updating of the electric field E and the magnetic field H is assumed to be shifted by ½ step. That is, at time t=1, the magnetic field H is indicated to be updated after the electric field E is updated.

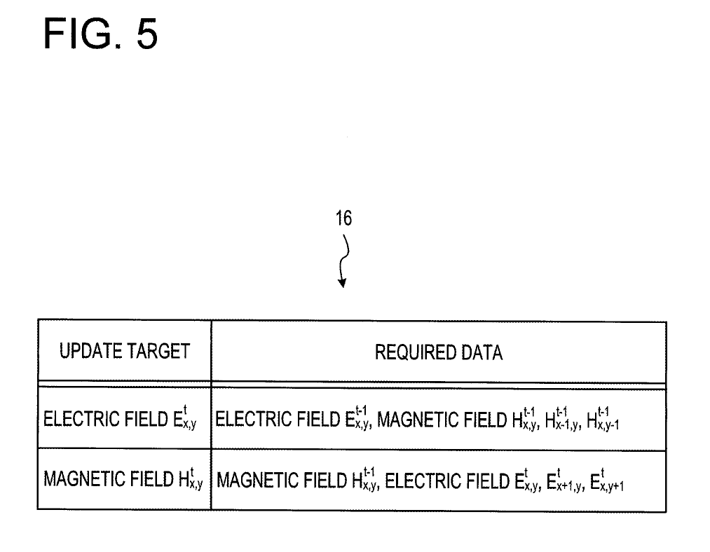

FIG. 5 is a diagram illustrating an example of a relationship between an electric field and a magnetic field in the two-dimensional FDTD method. Table 16 represented in FIG. 5 is a table in which update targets in the two-dimensional FDTD method are associated with necessary data. In Table 16, the position is represented by (x, y) and the time is represented by t. At this time, when the update target is the electric field E at position (x, y) and time t, the electric field E and the magnetic field H at position (x, y) and time t−1, the magnetic field H at position (x−1, y) and time t−1, and the magnetic field H at position (x, y−1) and time t−1 are required. Further, in Table 16, when the update target is the magnetic field H at position (x, y) and time t, the magnetic field H at position (x, y) and time t−1, the electric field E at position (x, y) and time t, the electric field E at position (x+1, y) and time t, and the electric field E at position (x, y+1) and time t are required.

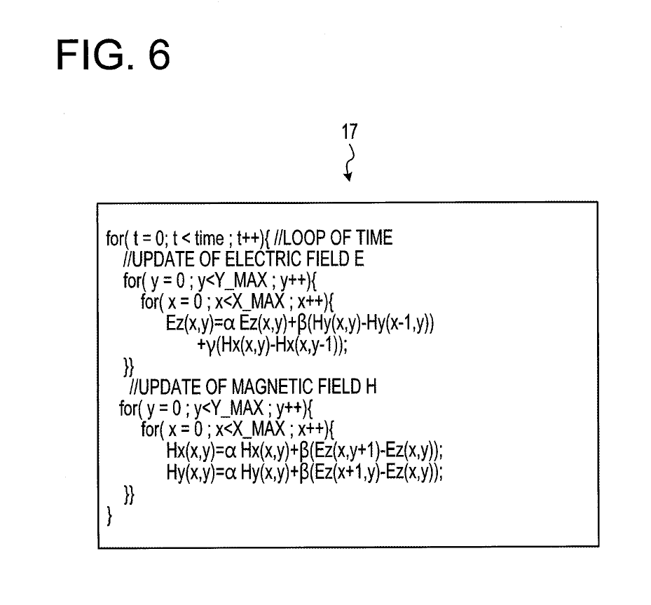

FIG. 6 is a diagram illustrating an example of a code when updating a magnetic field after updating an electric field. Code 17 illustrated in FIG. 6 is an example of a code that updates the magnetic field H at time t for all cells after updating the electric field E at time t for all cells in the area to be analyzed in the two-dimensional FDTD method. In the code 17, α, β, and γ are integers. In the code 17, for one cell, data is read five times and written once so as to update the electric field E, and a calculation is performed four times. Assuming that the data of each cell is 4 bytes, a memory access of 24 bytes occurs for four operations. That is, a memory access of 6 bytes occurs for each operation.

Similarly, in the code 17, for one cell, data is read five times and written twice, and a calculation is performed eight times so as to update the magnetic field H. Assuming that the data of each cell is 4 bytes, a memory access of 28 bytes occurs for eight operations. That is, a memory access of 3.5 bytes occurs for each operation. A memory performance and a calculation performance of a graphics processing unit (GPU) are, for example, a memory performance of 732 GB/s and a calculation performance of 10.6. Tflops in P100 of NVIDIA (registered trademark) Corporation. That is, a memory access of 0.69 bytes occurs for every operation in P100. In this way, the memory performance required by the FDTD method is slightly larger than that of the existing GPU, and a memory access becomes a bottleneck in the FDTD method.

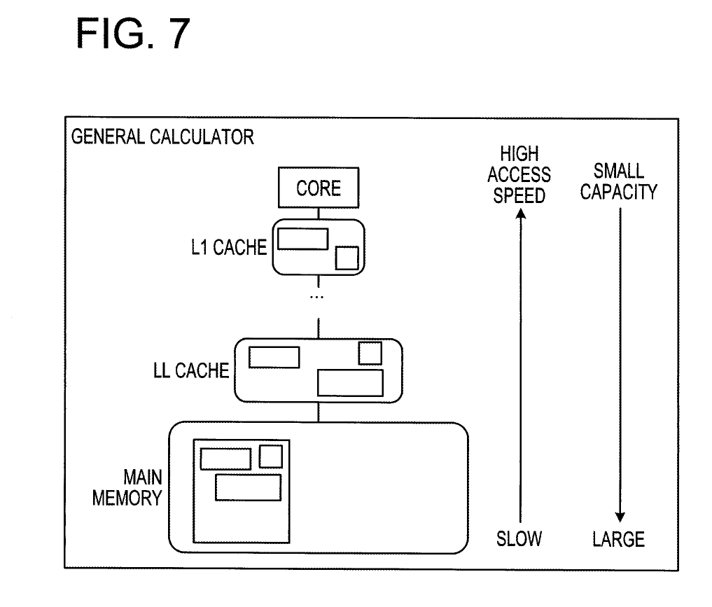

Next, a hierarchical memory structure will be described with reference to FIG. 7. FIG. 7 is a diagram illustrating an example of the hierarchical memory architecture. As illustrated in FIG. 7, recent computers have a cache memory of plural hierarchies between a core and a main memory. In such a hierarchical memory structure, the access speed and the capacity of each memory are different in each memory. In a hierarchical memory structure, when reading data from a low-speed main memory, data is stored in a high-speed cache memory. That is, when there is data in the cache memory, it is possible to read data at high speed. The data of the cache memory that has not been referred to for a predetermined time is overwritten with other data. In the example of FIG. 7, although the data stored in a L1 cache may be read at the highest speed, data which is not stored in the L1 to LL cache is read from the main memory and becomes a bottleneck.

Subsequently, the configuration of the information processing apparatus 100 will be described. As illustrated in FIG. 1, the information processing apparatus 100 includes a communication circuit 110, a display circuit 111, an operation circuit 112, a memory 120, and a control circuit 130. In addition to the functional circuits illustrated in FIG. 1, the information processing apparatus 100 may include various functional circuits of a computer in the related art, for example, functional circuits such as various input devices and audio output devices.

The communication circuit 110 is implemented by, for example, a network interface card (NIC). The communication circuit 110 is a communication interface that is connected to another information processing apparatus via a network (not illustrated) either in a wired or wireless manner, and is responsible for communication of information with another information processing apparatus. The communication circuit 110 receives data to be analyzed from, for example, another terminal. Further, the communication circuit 110 transmits the analysis result to another terminal.

The display circuit 111 is a display device that displays various types of information. The display circuit 111 is implemented by, for example, a liquid crystal display as a display device. The display circuit 111 displays various screens such as a display screen input from the control circuit 130.

The operation circuit 112 is an input device that receives various operations from the user of the information processing apparatus 100. The operation circuit 112 is implemented by, for example, a keyboard or a mouse as an input device. The operation circuit 112 outputs the operation input by the user to the control circuit 130 as operation information. The operation circuit 112 may be implemented by, for example, a touch panel as an input device, and the display device of the display circuit 111 and the input device of the operation circuit 112 may be integrated with each other.

The memory 120 is implemented by, for example, a semiconductor memory element such as a random access memory (RAM) or a flash memory, or a storage device such as a hard disk or an optical disk. The memory 120 includes an electric field memory 121 and a magnetic field memory 122. In addition, the memory 120 stores information used for processing in the control circuit 130. Further, in the present embodiment, descriptions have been made on an assumption of a state where the electric field memory 121 and the magnetic field memory 122 are stored in the main memory, but after completion of the calculation by the FDTD method, the data may be stored in a storage device such as a hard disk or a flash memory.

The electric field memory 121 stores an electric field component for each cell (element) with respect to the area to be analyzed in the FDTD method.

The magnetic field memory 122 stores a magnetic field component for each cell (element) with respect to the area to be analyzed in the FDTD method.

The control circuit 130 is implemented by executing a program stored in an internal storage device with the RAM as a work area by, for example, a central processing unit (CPU) or a micro processing unit (MPU). Further, the control circuit 130 may be implemented by an integrated circuit such as, for example, an application specific integrated circuit (ASIC) or a field programmable gate array (FPGA).

The control circuit 130 includes setting circuit 131 and an update circuit 132, and implements or executes the information processing function and operation described below. Further, the internal configuration of the control circuit 130 is not limited to the configuration illustrated in FIG. 1, and other configurations may be adopted as long as the information processing to be described later is performed.

The setting circuit 131 sets, for example, the parameter of the space to be analyzed input from the user as the update circuit 132. The parameter includes, for example, the permeability of the space, the conductivity, the initial states of the electric field and the magnetic field, or the updating equations corresponding to the sources of the electric field and the magnetic field. Further, the setting circuit 131 initializes the arrays corresponding to the respective cells of the electric field memory 121 and the magnetic field memory 122.

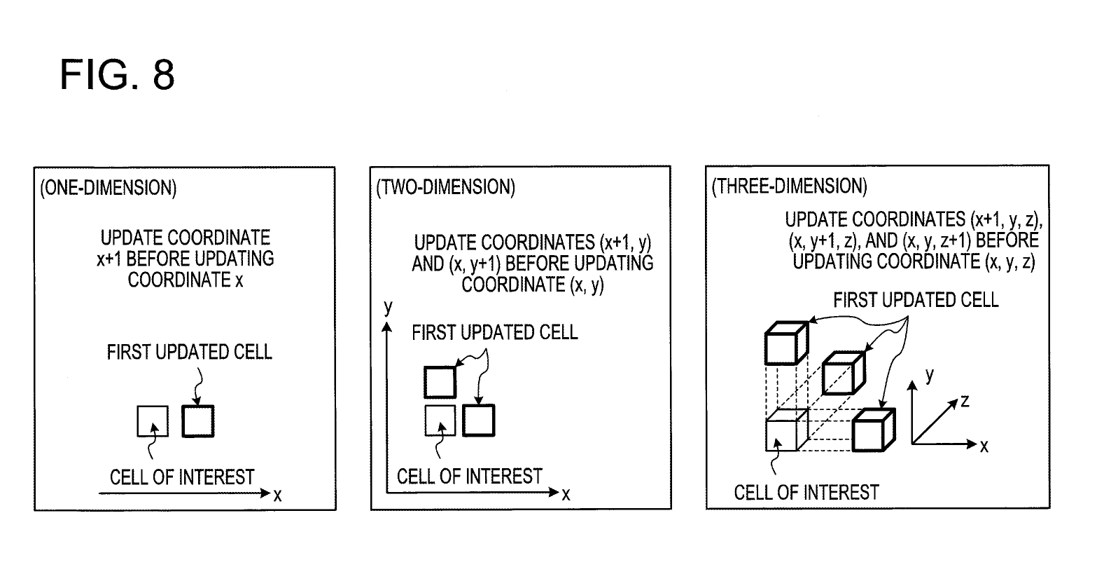

When the initialization of the array by the setting circuit 131 has been completed, the update circuit 132 starts updating the electric field component (electric field E) and the magnetic field component (magnetic field H) for each cell in the space to be analyzed. In the following description, the electric field E and the magnetic field H are also referred to as an electric field component and a magnetic field component, respectively. Further, in the following description, the electric field component and the magnetic field component are collectively referred to as an electromagnetic field component. Here, the constraints on the update order will be described with reference to FIGS. 8 to 10.

FIG. 8 is a diagram illustrating an example of a constraint of an update order. As illustrated in FIG. 8, in the one-dimensional FDTD method, the cell at coordinate x+1 is first updated before updating the cell of interest at coordinate x. In the two-dimensional FDTD method, the cells at coordinate (x+1, y) and coordinate (x, y+1) are first updated before updating the cell of interest at coordinate (x, y). In the three-dimensional FDTD method, the cells at coordinate (x+1, y, z), coordinate (x, y+1, z), and coordinate (x, y, z+1) are first updated before updating the cell of interest at coordinate (x, y, z). That is, the update circuit 132 imposes constraints on the update order so that the cells are updated in an order of the dependence relationship of the updating equation of the magnetic field. For example, in the areas represented by (0, 0) to (2, 2), the order of (2, 2)→(1, 2)→(0, 2)→(2, 1)→(1, 1)→(0, 1)→(2, 0)→(1, 0)→(0, 0) is satisfied. By providing constraints on the update order in this way, the update circuit 132 may update the electric field and the magnetic field for each cell.

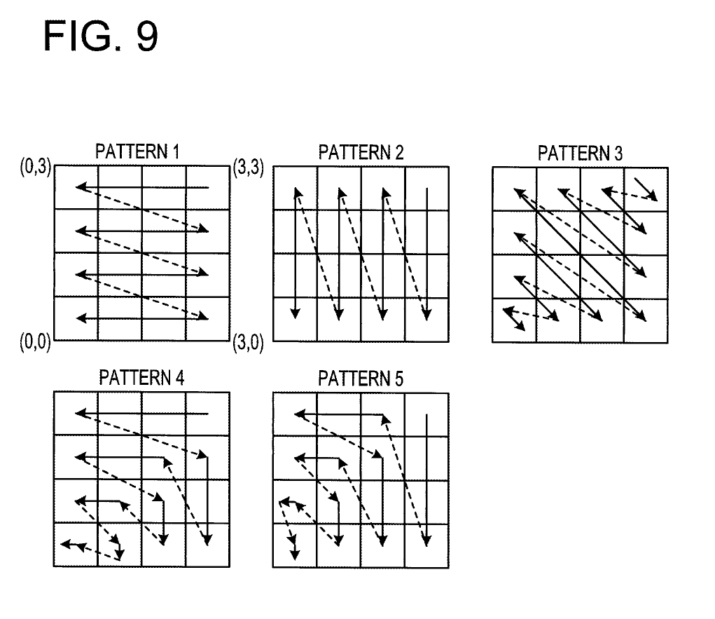

FIG. 9 is a diagram illustrating an example of a pattern of a cell update order. As illustrated in FIG. 9, the pattern of the cell update order may be, for example, the order represented in “pattern 1” to “pattern 5.” Further, in “pattern 3,” there is no order of updating the cells of the same arrow, and when the cells are included in the same arrow, the cells may be updated from any cell. That is, the update circuit 132 updates the cells in an order from the cell whose coordinate value in the area to be analyzed is the maximum value to the cell whose coordinate value is the minimum value.

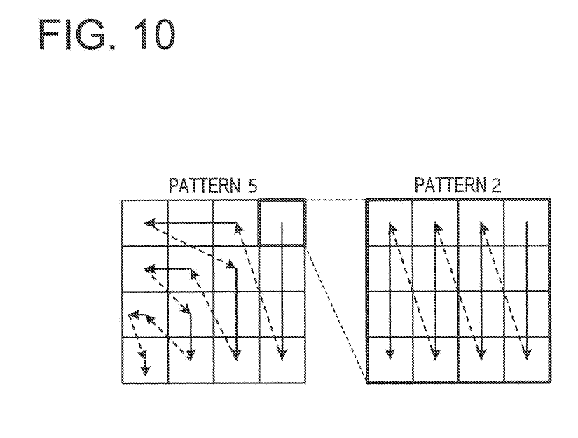

FIG. 10 is a diagram illustrating an example of a combination of patterns of the cell update order. As illustrated in FIG. 10, the patterns of the cell update order illustrated in FIG. 9 may be combined with each other. In the example of FIG. 10, the update order of processing blocks including a plurality of cells is referred to as “pattern 5,” and the update order of cells in the processing blocks is referred to as “pattern 2.”

When starting updating the electromagnetic field component, the update circuit 132 determines whether updating of the electromagnetic field components of all the cells has been completed. When it is determined that updating of the electromagnetic field components of all the cells has not been completed, the update circuit 132 selects one cell which has not been updated in the order of the dependence relationship of the updating equation of the magnetic field. That is, the update circuit 132 selects one cell which has not been updated according to the pattern of the cell update order illustrated in FIG. 9. The update circuit 132 updates the electric field component of the selected cell according to the constraints of the cell update order illustrated in FIG. 8, updates the magnetic field component of the cell, and then returns to a determination of whether updating of the electromagnetic field components of all the cells has been completed.

In the meantime, when it is determined that updating of the electromagnetic field components of all the cells has been completed, the update circuit 132 determines whether the calculation of all the steps has been completed. When it is determined that the calculation of all the steps has not been completed, the update circuit 132 advances the step of time by one step so as to update the electromagnetic field components of all the cells for the next step. Further, when it is determined that the calculation of all the steps has ended, the update circuit 132 ends updating the electromagnetic field components.

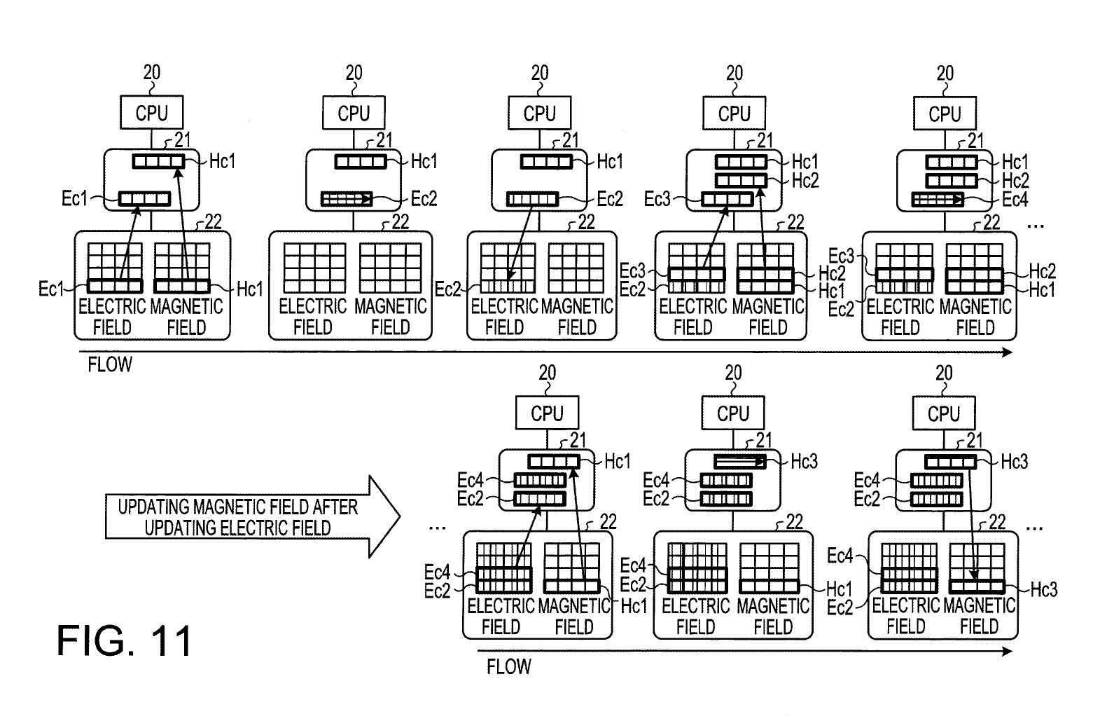

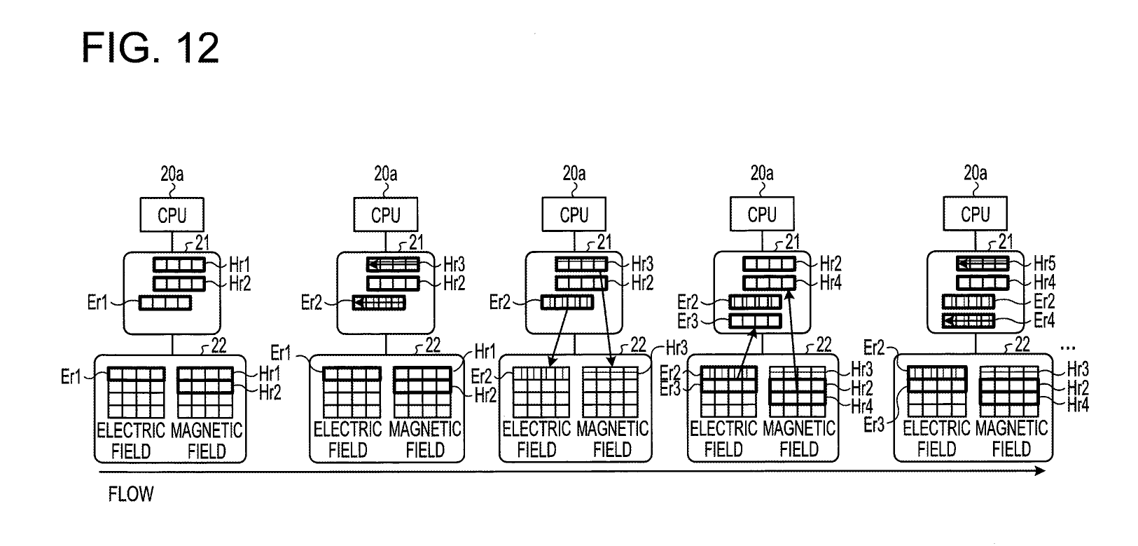

Here, the transition of the memory state for each method of updating the electromagnetic field components will be described with reference to FIGS. 11 and 12. FIG. 11 is a diagram illustrating an example of the transition of the memory state when updating a magnetic field after updating an electric field. That is, FIG. 11 corresponds to an updating method in the related art in which the memory access is a bottleneck. FIG. 11 represents the transition of the memory state according to the processing flow in the case of including the CPU 20, the cache memory 21, and the main memory 22. When the CPU 20 reads the electric field data Ec1 and the magnetic field data Hc1 from the main memory 22, the electric field data Ec1 and the magnetic field data Hc1 are cached in the cache memory 21. The CPU 20 stores the updated electric field data Ec2 in the cache memory 21. The electric field data Ec2 of the cache memory 21 is updated by overwriting the electric field data Ec1 of the main memory 22.

Next, when the CPU 20 reads the electric field data Ec3 and the magnetic field data Hc2 from the main memory 22, the electric field data Ec3 and the magnetic field data Hc2 are cached in the cache memory 21. At this time, the electric field data Ec2 stored in the cache memory 21 is overwritten by the electric field data Ec3. The CPU 20 stores the updated electric field data Ec4 in the cache memory 21. Thereafter, the CPU 20 repeats the process until the electric field data of the main memory 22 are all updated.

When updating of the electric field components has been completed, the CPU 20 starts updating the magnetic field components. When the CPU 20 reads the electric field data Ec2 and Ec4, and the magnetic field data Hc1 from the main memory 22, the electric field data Ec2 and Ec4, and the magnetic field data Hc1 are cached in the cache memory 21. That is, since the electric field data Ec2 and Ec4 which are once stored in the cache memory 21 at the time of updating the electric field component are overwritten by the subsequent process, the CPU 20 is read again from the main memory 22. The CPU 20 stores the updated magnetic field data Hc3 in the cache memory 21. The magnetic field data Hc3 of the cache memory 21 overwrites and updates the magnetic field data Hc1 of the main memory 22. In this way, in the example of FIG. 11, the electromagnetic field components of the cell are read from the low-speed main memory 22 by updating the electric field and the magnetic field, respectively.

FIG. 12 is a diagram illustrating an example of a transition of a memory state when updating an electric field and a magnetic field for each cell of interest. FIG. 12 corresponds to the updating method of the present embodiment. FIG. 12 represents the transition of the memory state according to the processing flow in the case of including the CPU 20a, the cache memory 21, and the main memory 22. Further, it is assumed that the CPU 20a also performs a process similar to that of the update circuit 132.

When the CPU 20a reads the electric field data Er1 and the magnetic field data Hr1 and Hr2 from the main memory 22, the electric field data Er1 and the magnetic field data Hr1 and Hr2 are cached in the cache memory 21. The CPU 20a stores the updated electric field data Er2 and magnetic field data Hr3 in the cache memory 21. The electric field data Er2 and the magnetic field data Hr3 of the cache memory 21 overwrite and update the electric field data Er1 and the magnetic field data Hr1 of the main memory 22, respectively. That is, immediately after the cached electric field component of the cell of interest is updated to the electric field data Er2, the CPU 20a updates the magnetic field component to the magnetic field data Hr3 by referring to the electric field data Er2 stored in the cache memory 21.

Next, when the CPU 20a reads the electric field data Er3 and the magnetic field data Hr4 from the main memory 22, the electric field data Er3 and the magnetic field data Hr4 are cached in the cache memory 21. At this time, the magnetic field data Hr3 stored in the cache memory 21 is overwritten with the magnetic field data Hr4. The CPU 20a stores the updated electric field data Er4 and magnetic field data Hr5 in the cache memory 21. At this time, the electric field data Er3 and the magnetic field data Hr2 stored in the cache memory 21 are overwritten by the electric field data Er4 and the magnetic field data Hr5, respectively. Thereafter, the CPU 20a repeats the process until the electric field data and the magnetic field data of the main memory 22 are all updated. In this way, in the example of FIG. 12, since the electric field data and the magnetic field data stored in the cache memory 21 are referred to, the number of accesses to the low-speed main memory 22 may be reduced. Further, in the example of FIG. 12, the electromagnetic field component may be updated with a single cache process.

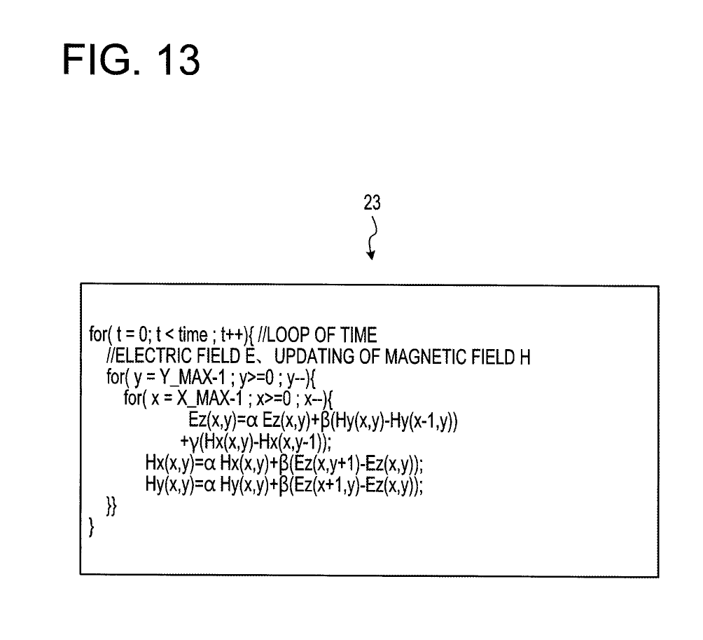

FIG. 13 is a diagram illustrating an example of a code when updating an electric field and a magnetic field for each cell of interest. Code 23 illustrated in FIG. 13 is an example of a code that updates the electric field E and the magnetic field H at time t for each cell of interest in the area to be analyzed in the two-dimensional FDTD method. Further, in the code 23, α, β, and γ are integers. In the code 23, memory accesses of the same number as that of the code 17 illustrated in FIG. 6 occur for one cell, but since the data used at the time of updating the electric field component may be read from the cache memory 21 at the time of updating the magnetic field component, the speed of memory access may be correspondingly increased.

In other words, the update circuit 132 updates the cells in the +1 direction of predetermined coordinates in N dimensions, stores the updated values in the cache memory 21, and then updates the cells at the predetermined coordinates using the stored values. Further, the update circuit 132 updates the electric field component of the cell at the predetermined coordinates, and updates the magnetic field components of the cells at the predetermined coordinates using the electric field component after the update of the cell having the predetermined coordinate and the cell in the +1 direction of the predetermined coordinate, and the electric field component before the update of the cell of the predetermined coordinate. The update circuit 132 also updates the cells in an order from the cell whose coordinate value in the area to be analyzed is the maximum value to the cell whose coordinate value is the minimum value.

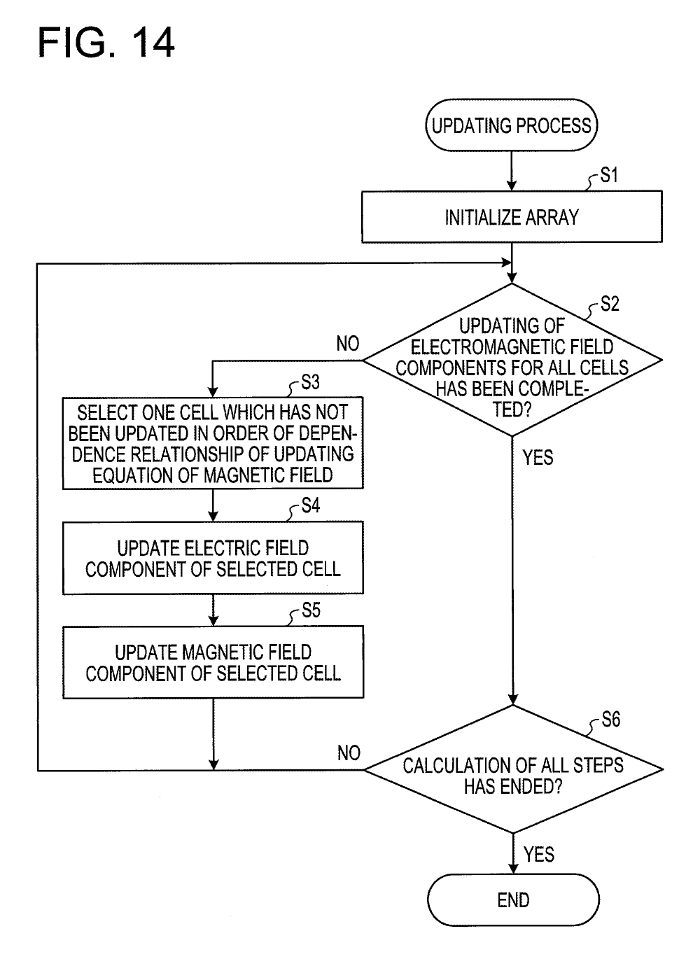

Next, descriptions will be made on the operation of the information processing apparatus 1 according to the first embodiment. FIG. 14 is a flowchart illustrating an example of an updating process according to the first embodiment.

The setting circuit 131 initializes the arrays corresponding to the respective cells of the electric field memory 121 and the magnetic field memory 122 (step S1).

When the initialization of the array by the setting circuit 131 has been completed, the update circuit 132 starts updating the electromagnetic field component for each cell in the space to be analyzed. The update circuit 132 determines whether updating of the electromagnetic field components of all the cells has been completed (step S2). When it is determined that the updating of the electromagnetic field components of all the cells has not been completed (“No” in step S2), the update circuit 132 selects one cell which has not been updated in an order of the dependence relationship of the updating equation of the magnetic field (step S3).

The update circuit 132 updates the electric field component of the selected cell (step S4). The update circuit 132 updates the magnetic field component of the selected cell (step S5) and returns to step S2.

In the meantime, when it is determined that updating of the electromagnetic field components of all cells has been completed (“Yes” in step S2), the update circuit 132 determines whether the calculation of all the steps has ended (step S6). When it is determined that the calculation of all the steps has not ended (“No” in step S6), the update circuit 132 advances the step of time by one, and returns to step S2.

When it is determined that the calculation of all the steps has ended (“Yes” in step S6), the update circuit 132 ends updating the electromagnetic field component for each cell in the space to be analyzed. As a result, the information processing apparatus 100 may reduce the number of memory accesses at the time of updating in the FDTD method. Further, the information processing apparatus 100 may update the electromagnetic field component of each cell by one scanning of the main memory.

In addition, in the first embodiment, the cache memory 21 has been described as one hierarchy, but the present disclosure is not limited to this. For example, a multi-layer cache memory such as a three-layer cache memory from the L1 cache to the L3 cache may be used.

As described above, the information processing apparatus 100 is an information processing apparatus that performs a process of the N-dimensional FDTD method. That is, the information processing apparatus 100 updates the cells in the +1 direction of the predetermined coordinates of the N dimension, stores the updated values in the cache memory, and then uses the stored values to update the cells of the predetermined coordinates. As a result, the information processing apparatus 100 may reduce the number of memory accesses at the time of updating in the FDTD method.

In addition, the information processing apparatus 100 updates the electric field components of the cell at the predetermined coordinates and updates the magnetic field components of the cell at the predetermined coordinates using the electric field component after the update of the cell at the predetermined coordinates and the cell in the +1 direction of the predetermined coordinates, and the magnetic field component before the update of the cell at the predetermined coordinates. As a result, the information processing apparatus 100 may acquire a portion of data used at the time of updating the electromagnetic field component from the cache memory.

Further, the information processing apparatus 100 updates the cells in an order from the cell whose coordinate value is the maximum value in the area to be analyzed to the cell whose coordinate value is the minimum value. As a result, the information processing apparatus 100 may acquire a portion of data used at the time of updating the electromagnetic field component from the cache memory.

### Second Embodiment

In the first embodiment, descriptions have been made on the updating of the electromagnetic field component in the CPU 20a. However, such descriptions may well be applied to the updating of the electromagnetic field component using the GPU, and the embodiment in this case will be described as a second embodiment. The same components as those of the information processing apparatus 100 according to the first embodiment are denoted by the same reference numerals, and redundant descriptions of the configurations and operations are omitted.

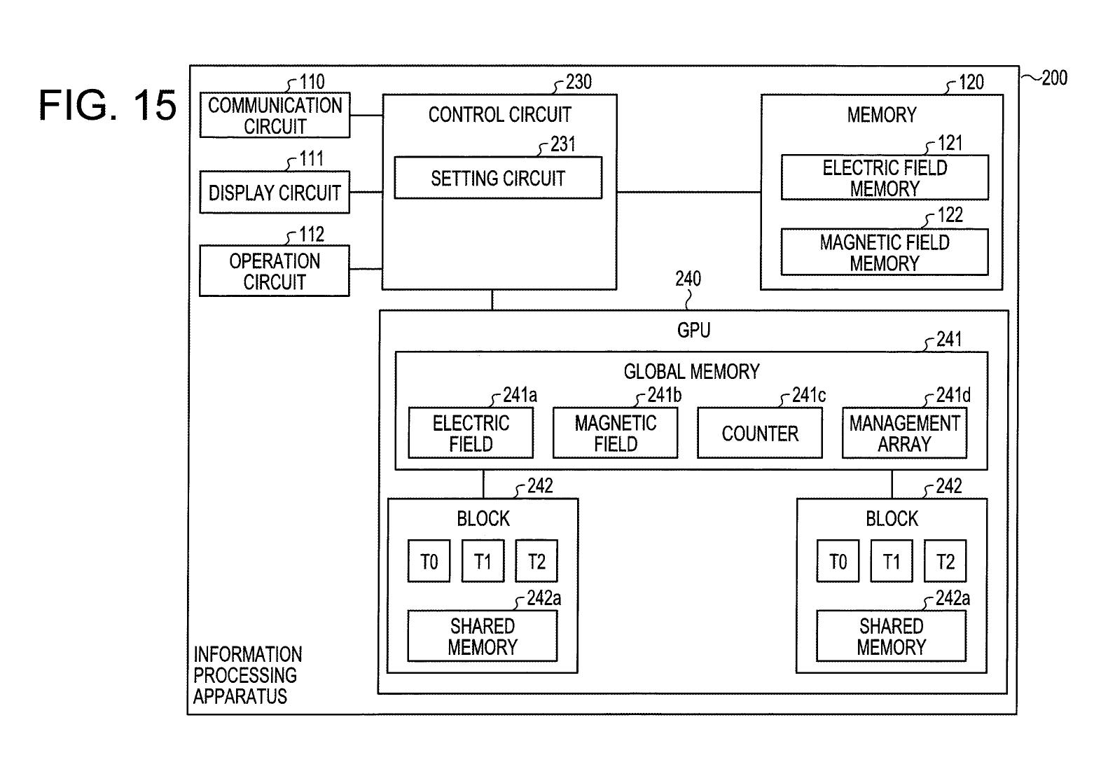

FIG. 15 is a block diagram illustrating an example of the configuration of the information processing apparatus according to the second embodiment. The information processing apparatus 200 illustrated in FIG. 15 includes a control circuit 230 instead of the control circuit 130, and further includes a GPU 240, as compared with the information processing apparatus 100 of the first embodiment. In addition, the control circuit 230 includes a setting circuit 231 instead of the setting circuit 131 as compared with the control circuit 130, and excludes the update circuit 132.

Similarly to the setting circuit 131 of the first embodiment, the setting circuit 231 sets, for example, the parameter of the space to be analyzed input from the user as the GPU 240. Further, the setting circuit 231 initializes the arrays E and H corresponding to the respective cells of the electric field memory 121 and the magnetic field memory 122, and the time t. The setting circuit 231 outputs the initialized electric field data and magnetic field data to the GPU 240. Further, the electric field data and the magnetic field data may transfer a direct memory access (DMA) from the electric field memory 121 and the magnetic field memory 122 to the GPU 240.

When outputting the electric field data and the magnetic field data to the GPU 240, the setting circuit 231 calls a GPU function and instructs the GPU 240 to execute the process of updating E and H. Upon receiving the update completion notice from the GPU 240, the setting circuit 231 refers to the electric field memory 121 and the magnetic field memory 122 and displays the analysis result on, for example, the display circuit 111. Further, the electric field data and the magnetic field data after the process of updating E and H in the GPU 240 are stored from the GPU 240 in the electric field memory 121 and the magnetic field memory 122 using, for example, the DMA transfer.

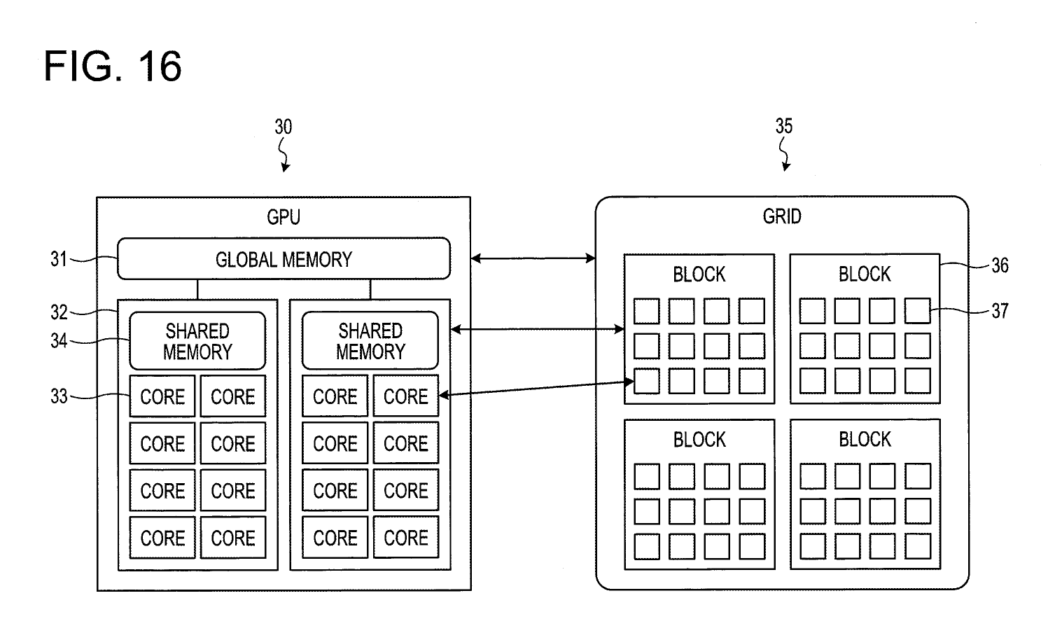

Here, the configuration of the GPU will be described with reference to FIG. 16. FIG. 16 is a diagram illustrating an example of the configuration of the GPU. The GPU 30 in FIG. 16 is an example of a hardware configuration of the GPU 240. The GPU 30 includes a global memory 31 and a plurality of streaming processors 32. The streaming processor 32 includes a plurality of cores 33 and a shared memory 34 that is shared by the respective cores 33. Further, the global memory 31 is also called an off-chip memory and is a memory of a low speed but a large capacity. The shared memory 34 is also called an on-chip memory and is a memory of a high speed but a small capacity.

A grid 35 in FIG. 16 is an example of a hierarchical thread structure corresponding to the GPU 30. The grid 35 is an example of a hierarchical thread structure of, for example, a compute unified device architecture (CUDA) (registered trademark). The grid 35 includes a plurality of blocks 36. Each block 36 includes a plurality of threads 37. Each thread 37 in the same block 36 may share the data on the same shared memory 34 and synchronize during execution. Further, the number of threads 37 is larger than the number of cores 33. Also, the block 36 is asynchronously assigned to the streaming processor 32. Therefore, in order to synchronize with the thread 37 between the blocks 36, the process of the GPU 30 is ended once. That is, since the data in the shared memory 34 being processed may not be accessed, such data is recorded in the global memory 31 which is accessible from the plurality of blocks 36.

Referring back to the description of FIG. 15, the GPU 240 includes a global memory 241 and a plurality of blocks 242. The global memory 241 includes areas such as an electric field 241a, a magnetic field 241b, a counter 241c, and a management array 241d. The global memory 241 corresponds to the main memory 22 of the first embodiment and corresponds to the global memory 31 of FIG. 16.

The electric field data is stored in the electric field 241a when performing the process of updating E and H with the GPU 240. The electric field data is updated at any time as the electric field component is updated. The electric field 241a is updated by each block 242 in units of processing blocks including a plurality of cells.

The magnetic field data is stored in the magnetic field 241b when performing the process of updating E and H with the GPU 240. The magnetic field data is updated at any time as the magnetic field component is updated. Similarly to the electric field 241a, the magnetic field 241b is updated by each block 242 in units of processing blocks including a plurality of cells.

The counter 241c is a counter for exclusive control and designates a processing block to be updated by each block 242 using the counter value. That is, the counter 241c is used to dynamically allocate processing blocks in ascending order of dependence relationship of updating equations of the magnetic field to the block 242 that is started asynchronously. That is, all the blocks 242 in the counter 241c share one counter.

The management array 241d is an arrangement that manages the update state of each of the electric field component and the magnetic field component. The management array 241d has a value at time t for each of the processing blocks of the electric field 241a and the magnetic field 241b. That is, the management array 241d confirms the update state of the other block 242 and may wait. That is, since the magnetic field component in the updating of the electric field component and the electric field component in the updating of the magnetic field component are referred to from the area of the other block 242 (processing block), the management array 241d is used as a flag indicating whether the reference point has been updated.

The block 242 corresponds to the streaming processor 32 in the hardware configuration of the GPU 30 in FIG. 16. That is, the block 242 corresponds to the block 36 in the hierarchical thread structure of the grid 35. The block 242 includes threads TO to T2 corresponding to the thread 37 in FIG. 16, and a shared memory 242a corresponding to the shared memory 34 in FIG. 16. The shared memory 242a is a memory accessible from the threads TO to T2 and corresponds to the cache memory 21 of the first embodiment.

Each block 242 corresponds to the update circuit 132 of the first embodiment and starts updating the electric field component and the magnetic field component for each processing block in the space to be analyzed according to an instruction from the setting circuit 231. That is, the block 242 updates the electromagnetic field components in an order of the dependence relationship of the updating equations of the magnetic field in units of processing blocks including a plurality of cells. That is, the pattern of the update order of each processing block according to the second embodiment corresponds to the pattern of the update order of each cell according to the first embodiment.

The block 242 executes an updating process of the electromagnetic field component (the process of updating E and H) according to calling of the GPU function of the setting circuit 231. The block 242 executes an exclusive increment operation of the counter 241c. That is, the counter 241c does not accept access from the other block 242 until a certain block 242 acquires the counter value before the increment and increments the counter 241c.

The block 242 determines whether updating of all processing blocks (elements) has ended. When it is determined that updating of all the processing blocks has ended, the block 242 increments the time t. The block 242 determines whether the time t is equal to or less than the predetermined time T. When it is determined that the time t is equal to or less than the predetermined time T, the block 242 executes the process of updating E and H for the incremented time t. When it is determined that the time t is greater than the predetermined time T, the block 242 ends the process of updating E and H.

In the meantime, when it is determined that updating of all the processing blocks has not ended, the block 242 calculates the calculation coordinates based on the counter value of the counter 241c. The block 242 refers to the management array 241d and determines whether updating of the processing block to be referred to when updating the electric field component of the processing block of interest has been completed. When it is determined that the updating of the processing block to be referred to has not been completed, the block 242 continues to refer to the management array 241d.

When it is determined that the updating of the processing block to be referred to has been completed, the block 242 updates the electric field component of the processing block of interest. When the updating of the electric field component of the processing block of interest has been completed, the block 242 refers to the management array 241d and determines whether updating of the processing block to be referred to in the updating of the magnetic field component of the processing block of interest has been completed. When it is determined that the updating of the processing block to be referred to has not been completed, the block 242 continues to refer to the management array 241d.

When it is determined that the updating of the processing block to be referred to has been completed, the block 242 updates the magnetic field component of the processing block of interest. When the magnetic field component of the processing block of interest has been updated, the block 242 determines that the updating of the electromagnetic field component of the processing block of interest has been completed, and proceeds to a process of updating E and H of the next processing block.

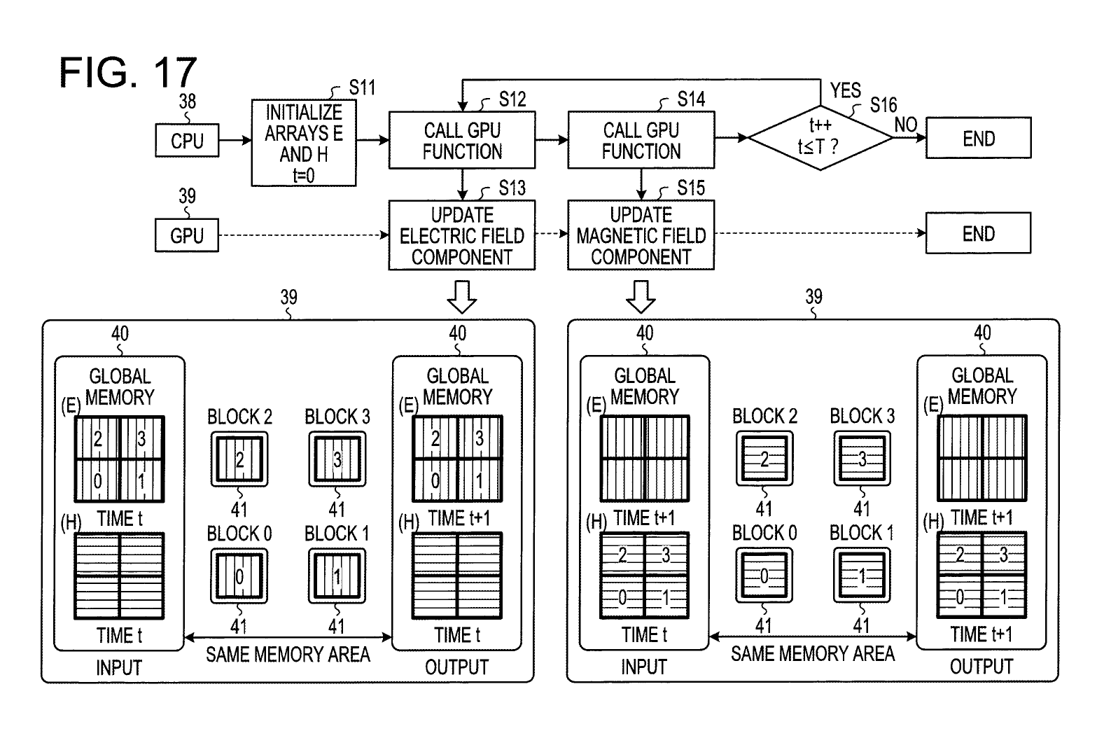

Here, an updating method of updating a magnetic field after updating an electric field in the related art will be described with reference to FIG. 17. FIG. 17 is a diagram illustrating an example of a case of updating a magnetic field after updating an electric field in the GPU. In FIG. 17, the CPU 38 and the GPU 39 perform a process of updating electromagnetic field components. The GPU 39 includes a global memory 40 and a block 41. Further, in the description of FIG. 17, the processing block is assumed to be four processing blocks, that is, “block 0” to “block 3.”

The CPU 38 initializes the arrays E and H corresponding to the electromagnetic field components and sets time t=0 (step S11). The CPU 38 outputs the initialized data to the GPU 39. The GPU 39 stores the initialized data in the global memory 40. The CPU 38 calls the GPU function (step S12). The GPU 39 updates the electric field component according to the call (step S13). At this time, the block 41 processes “block 0” to “block 3” of the electric field component at the time t, and the GPU 39 stores the blocks in the same area of the global memory 40 as the electric field component at the time t+1.

When the updating of the electric field component has been completed, the CPU 38 calls the GPU function again (step S14). The GPU 39 updates the magnetic field component according to the call (step S15). The block 41 processes “block 0” to “block 3” of the magnetic field component at the time t, and the GPU 39 stores the blocks in the same area of the global memory 40 as the magnetic field component at the time t+1. At this time, the value of the electric field component updated by the other block 41 is referred to when updating the magnetic field component. Also, the value of the magnetic field component updated by the other block 41 is similarly referred to when updating the electric field component. Therefore, in the example of FIG. 17, updating the electric field component and updating the magnetic field component are separated into separate GPU functions in order to obtain data consistency. That is, in the example of FIG. 17, the two GPU functions that update the electric field component and the magnetic field component, respectively, are repeated until the time L≤T (step S16).

As described above, in the example of FIG. 17, reading and writing from the global memory 40 becomes necessary for all elements (processing blocks) when updating the electromagnetic field component. That is, in the example of FIG. 17, it is determined by the bandwidth of the global memory 40 (off-chip memory). In the second embodiment, the electromagnetic field component is updated within the same GPU function, thereby reducing the number of accesses to the global memory 40 and increasing the speed.

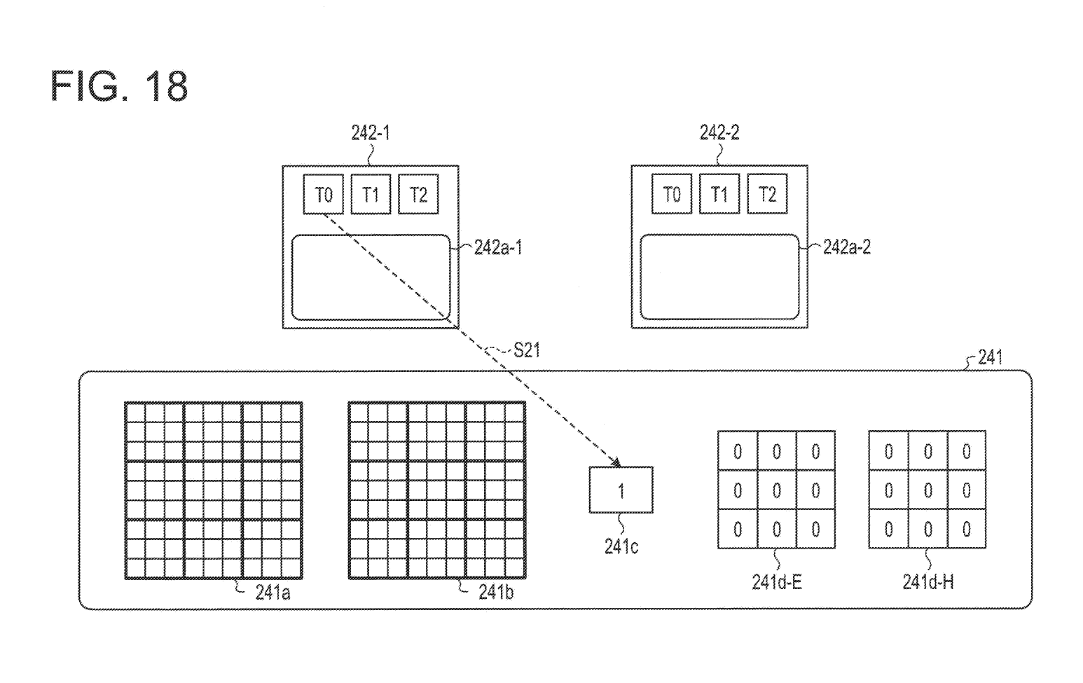

Subsequently, the transition of the memory state in the updating process according to the second embodiment will be described with reference to FIGS. 18 to 27. FIGS. 18 to 27 are diagrams illustrating an example of the transition of the memory state in the updating process. In the examples of FIGS. 18 to 27, descriptions will be made on the case where two blocks 242 of block 242-1 and block 242-2 perform the process of updating E and H. Further, the management array 241d includes an electric field management array 241d-E and a magnetic field management array 241d-H. It is assumed that the electric field 241a and the magnetic field 241b in FIGS. 18 to 27 have nine processing blocks. In each processing block, the processing block at the top right is “block 0,” the left side of the “block 0” is “block 1,” the lower portion of the “block 0” is “block 2,” the left side of the “block 1” is “block 3,” and the lower portion of the “block 1” is “block 4.” Further, in each processing block, the lower portion of the “block 2” is “block 5,” the lower portion of the “block 3” is “block 6,” the lower portion of the “block 4” is “block 7,” and the lower portion of the “block 6” is “block 8.”

As illustrated in FIG. 18, the thread TO of the block 242-1 increments the counter 241c (step S21). In the counter 241c, the counter value changes from “0” to “1.”

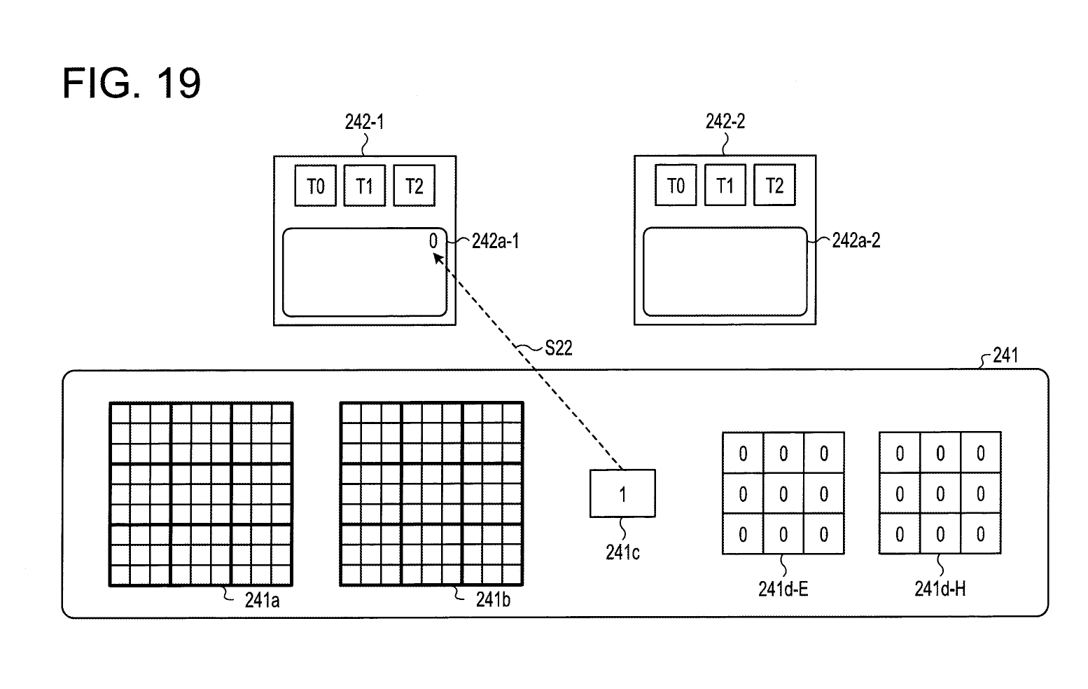

As illustrated in FIG. 19, the thread TO of the block 242-1 acquires the counter value “0” before the increment from the counter 241c and stores the acquired counter value in the shared memory 242a-1 (step S22).

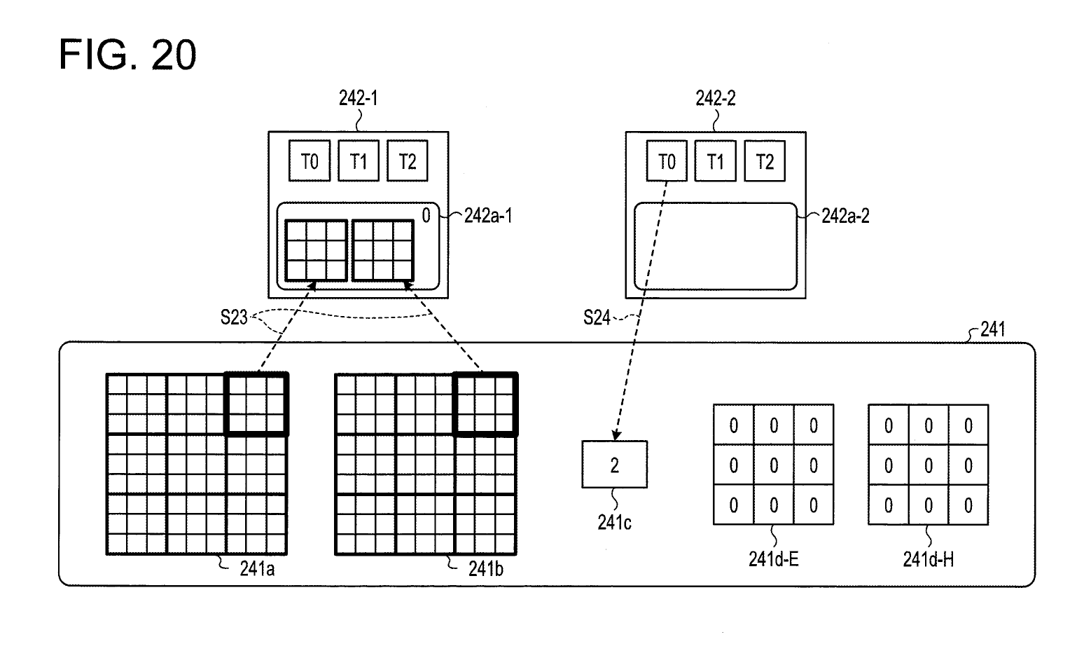

As illustrated in FIG. 20, the block 242-1 stores the electric field data and the magnetic field data of “block 0” having the largest coordinate value among the processing blocks of the electric field 241a and the magnetic field 241b in the shared memory 242a-1 (step S23). Further, the thread TO of the block 242-2 increments the counter 241c (step S24). In the counter 241c, the counter value changes from “1” to “2.”

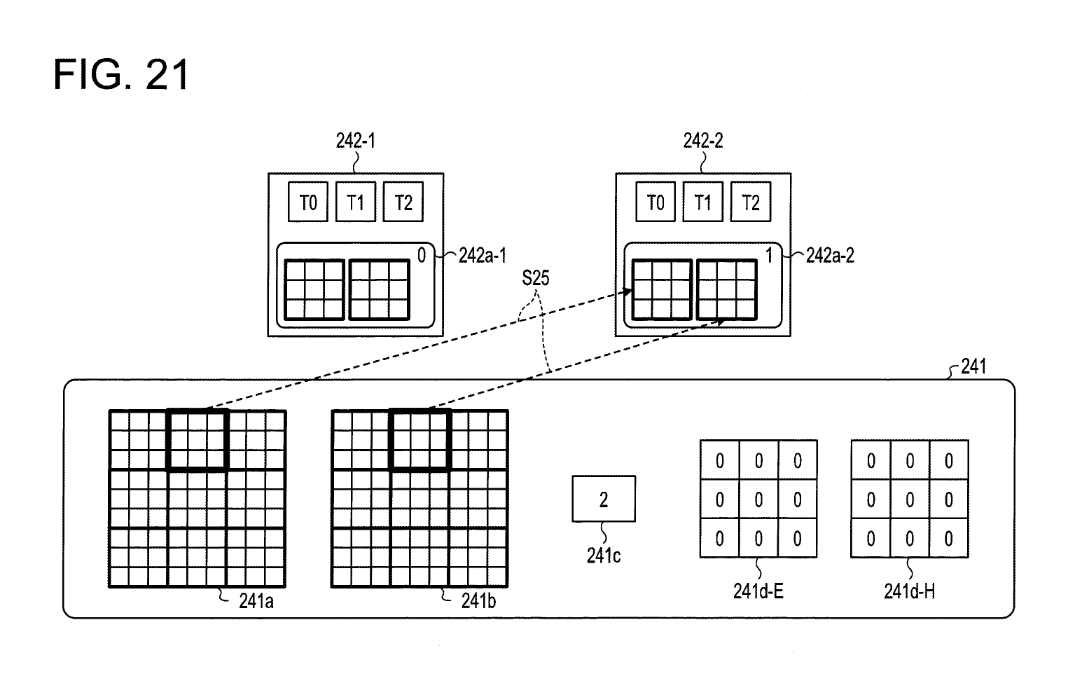

As illustrated in FIG. 21, the block 242-2 stores the electric field data and the magnetic field data of the “block 1” on the left side of the “block 0” in the shared memory 242a-2 based on the constraint of the update order among the processing blocks of the electric field 241a and the magnetic field 241b (step S25).

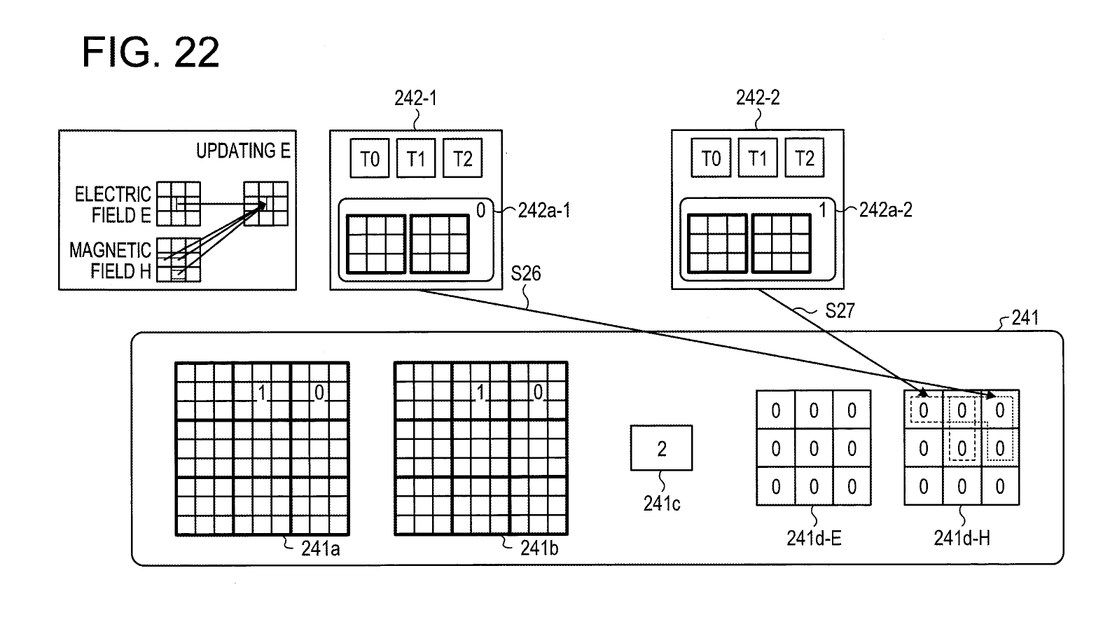

As illustrated in FIG. 22, the block 242-1 refers to the management array 241d-H of the magnetic field. When the time corresponding to the processing block enclosed by the dotted line is t=0, the block 242-1 determines that the updating of the processing block referred to at the time of calculating the electric field at the time t=1 of the “block 0” has been completed (step S26). Similarly, the block 242-2 refers to the management array 241d-H of the magnetic field. When the time corresponding to the processing block enclosed by the broken line is t=0, the block 242-2 determines that the updating of the processing block referred to at the time of calculating the electric field at the time t=1 of the “block 1” has been completed (step S27). That is, when the time corresponding to the processing block enclosed by the dotted line of the management array 241d-H of the magnetic field is t, the block 242-1 may calculate the electric field at the time t+1. Further, when the time corresponding to the processing block enclosed by the broken line of the management array 241d-H of the magnetic field is t, the block 242-2 may calculate the electric field at the time t+1.

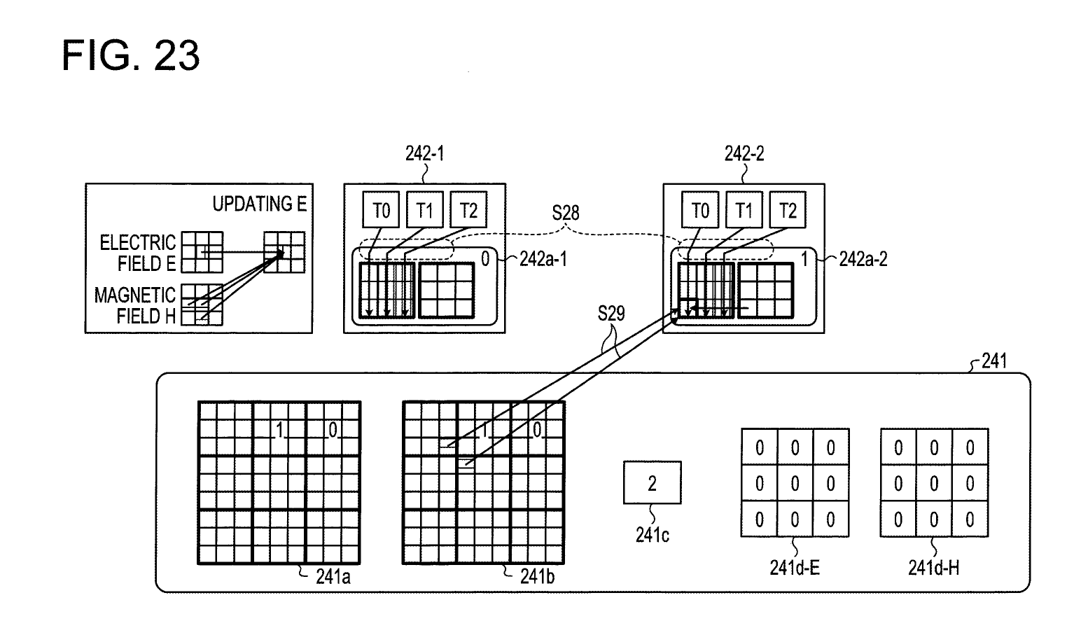

As illustrated in FIG. 23, the blocks 242-1 and 242-2 update the cells in the processing block with the threads TO to T2 for the processing blocks of the electric field 241a, that is, “block 0” and “block 1,” respectively (step S28). That is, the block 242-1 and the block 242-2 correspond to the area including a plurality of cells (processing block), and a plurality of threads perform a parallel processing within the area so as to update the cells. At this time, when using the magnetic field data of the cells included in the processing block outside the assigned area, the block 242-1 and the block 242-2 acquire the magnetic field data from the cells of the processing block outside the assigned area. In FIG. 23, the thread TO of the block 242-2 acquires the magnetic field data from the magnetic field 241b of the global memory 241 when updating the cell at the lower left corner among the electric field data of the processing block “block 1” (step S29).

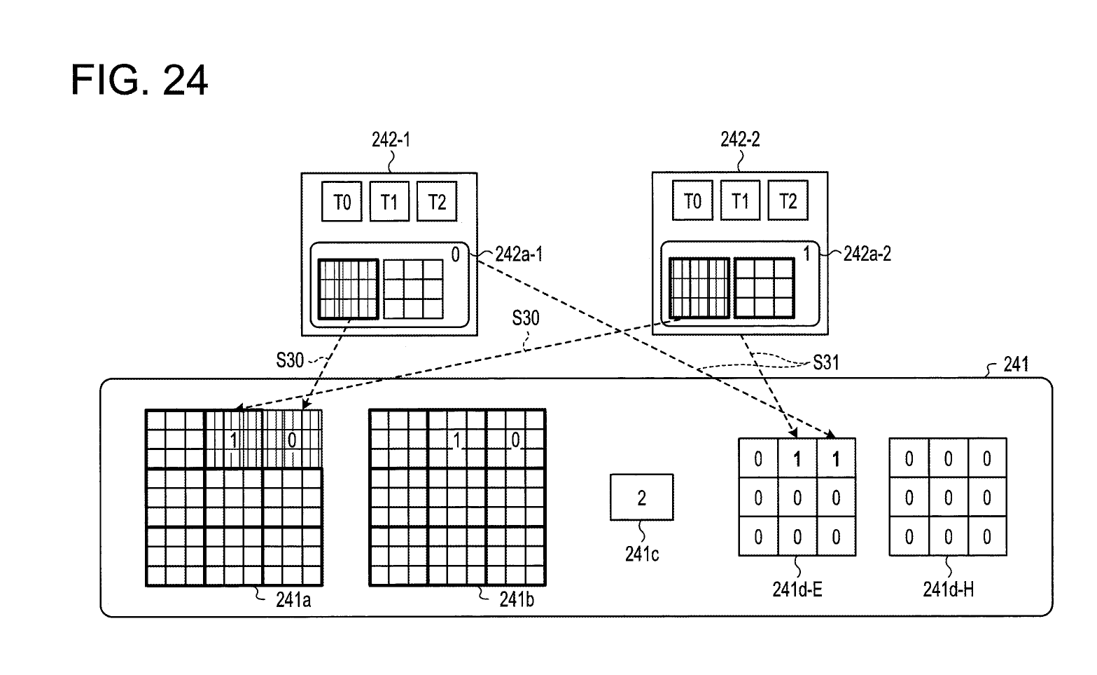

As illustrated in FIG. 24, when the calculation of the electric field data has been completed, the block 242-1 records and updates the electric field data in the processing block “block 0” of the electric field 241a of the global memory 241 from the shared memory 242a-1. Similarly, when the calculation of the electric field data has been completed, the block 242-2 records and updates the electric field data in the processing block “block 1” of the electric field 241a of the global memory 241 from the shared memory 242a-2 (step S30). Further, the block 242-1 updates the portion corresponding to the processing block “block 0” of the management array 241d-E of the electric field to time t=1. Similarly, the block 242-2 updates the portion corresponding to the processing block “block 1” of the management array 241d-E of the electric field to time t=1 (step S31).

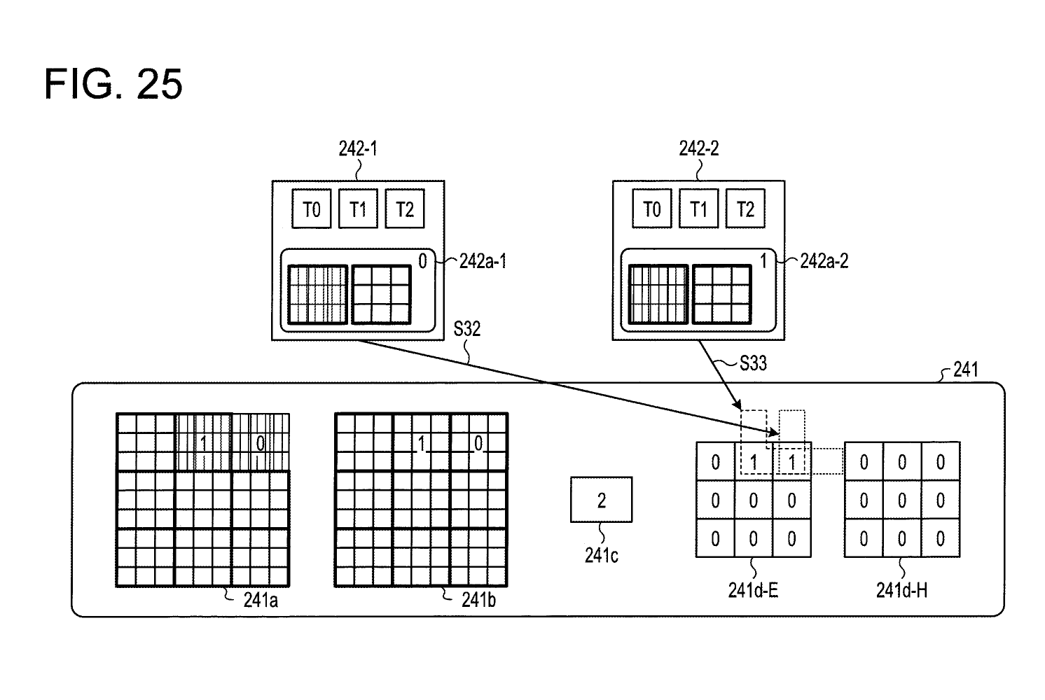

As illustrated in FIG. 25, the block 242-1 refers to the management array 241d-E of the electric field. When the time corresponding to the processing block enclosed by the dotted line in the figure is t=1, the block 242-1 determines that the updating of the processing block referred to at the time of calculating the magnetic field at the time t=1 of “block 0” has been completed (step S32). Similarly, the block 242-2 refers to the management array 241d-E of the electric field. When the time corresponding to the processing block enclosed by the broken line in the figure is t=1, the block 242-2 determines that the updating of the processing block to be referred to at the time of calculating the magnetic field at the time t=1 of “block 1” has been completed (step S33). That is, when the time corresponding to the processing block enclosed by the dotted line of the management array 241d-E of the electric field is t+1, the block 242-1 may calculate the magnetic field at time t+1. Further, when the time corresponding to the processing block enclosed by the broken line of the management array 241d-E of the electric field is t+1, the block 242-2 may calculate the magnetic field at the time t+1.

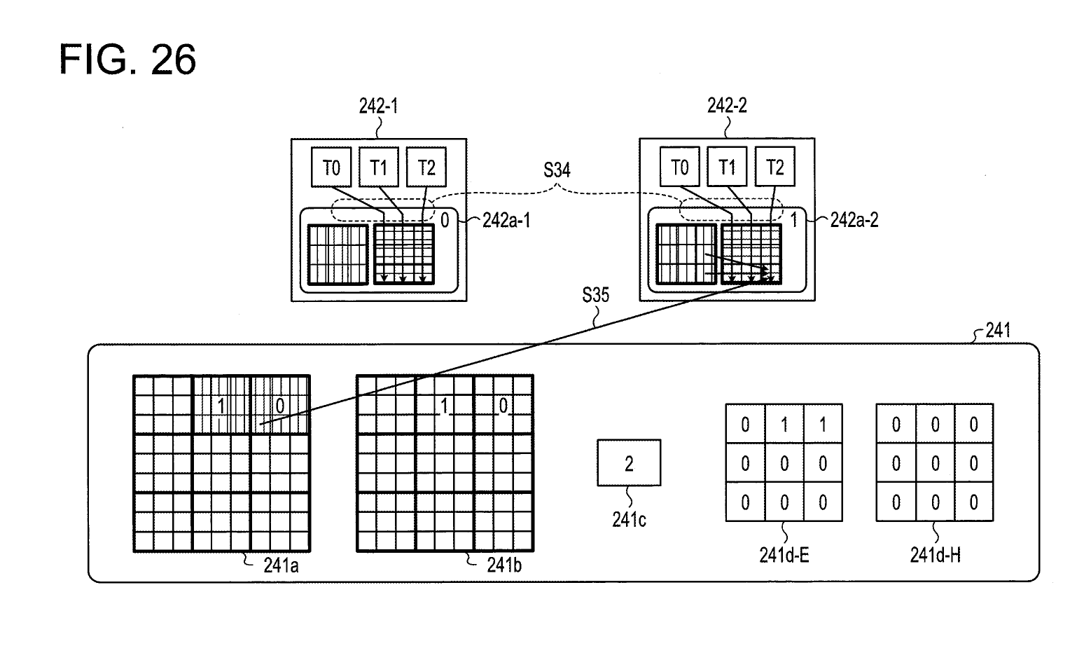

As illustrated in FIG. 26, the blocks 242-1 and 242-2 update the cells in the processing block with the threads TO to T2 with respect to the processing blocks of the magnetic field 241b, that is, “block 0” and “block 1,” respectively (step S34). At this time, when using the electric field data of the cells included in the processing block outside the assigned area, the blocks 242-1 and 242-2 acquire the magnetic field data from the cells of the processing block outside the assigned area. In FIG. 26, the thread T2 of the block 242-2 acquires the electric field data from the electric field 241a of the global memory 241 when updating the cell at the right lower corner among the magnetic field data of the processing block “block 1” (step S35).

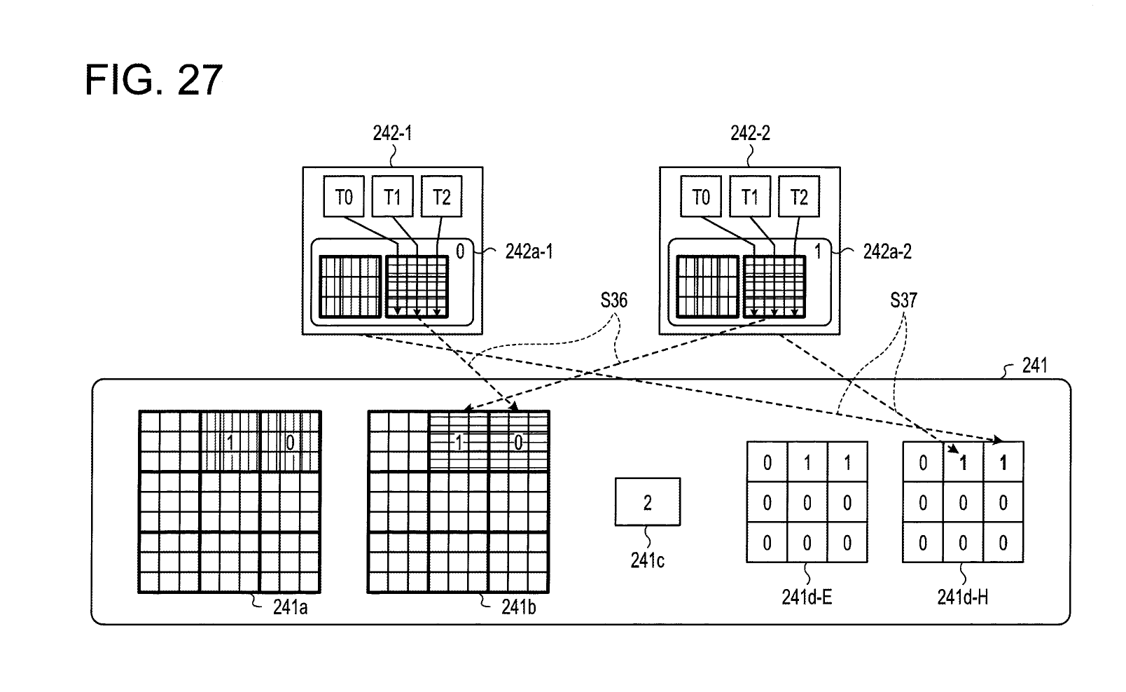

As illustrated in FIG. 27, when the calculation of the magnetic field data has been completed, the block 242-1 records and updates the magnetic field data to the processing block “block 0” of the magnetic field 241b of the global memory 241 from the shared memory 242a-1. Similarly, when the calculation of the magnetic field data has been completed, the block 242-2 records and updates the magnetic field data to the processing block “block 1” of the magnetic field 241b of the global memory 241 from the shared memory 242a-2 (step S36).

Further, the block 242-1 updates the portion corresponding to the processing block “block 0” of the management array 241d-H of the magnetic field to the time t=1. Similarly, the block 242-2 updates the position corresponding to the processing block “block 1” of the management array 241d-H of the magnetic field to the time t=1 (step S37). That is, the block 242-1 and the block 242-2 determine a processing block (cell) to be updated based on the value of the counter 241c, and store the update result of the determined processing block (cell) in the management array 241d.

The blocks 242-1 and 242-2 repeat steps S21 to S37 for all processing blocks of the electric field 241a and the magnetic field 241b. Thereafter, the blocks 242-1 and 242-2 repeat the steps S21 to S37 until the predetermined time T, thereby obtaining the analysis result up to the predetermined time T.

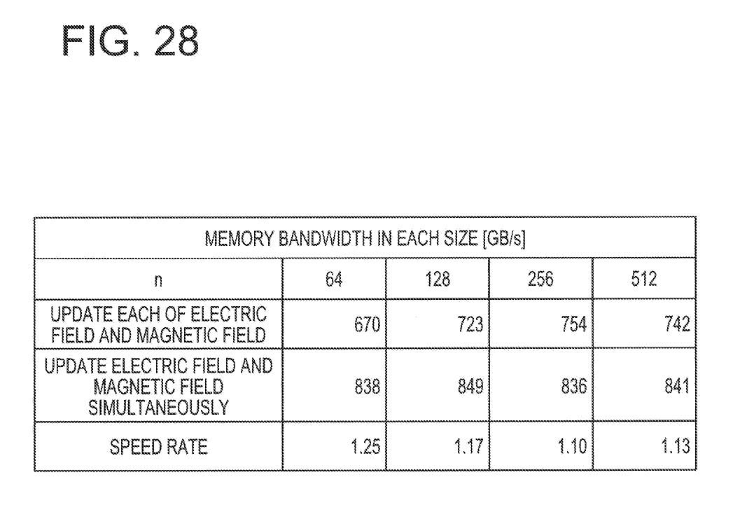

FIG. 28 is a diagram illustrating an example of performance evaluation in a three-dimensional FDTD method. In FIG. 28, the above-described P100 is used as the GPU. The symbol “n” indicates an input size. That is, the method is an n×n×n three-dimensional FDTD method. Time t is assumed to be 100 steps. As illustrated in FIG. 28, when updating the electric field and the magnetic field as the GPU mounting of the second embodiment at the same time as compared with the case of updating the electric field and the magnetic field as the GPU mounting in the related art, respectively, the speed is increased by 1.10 to 1.25 times.

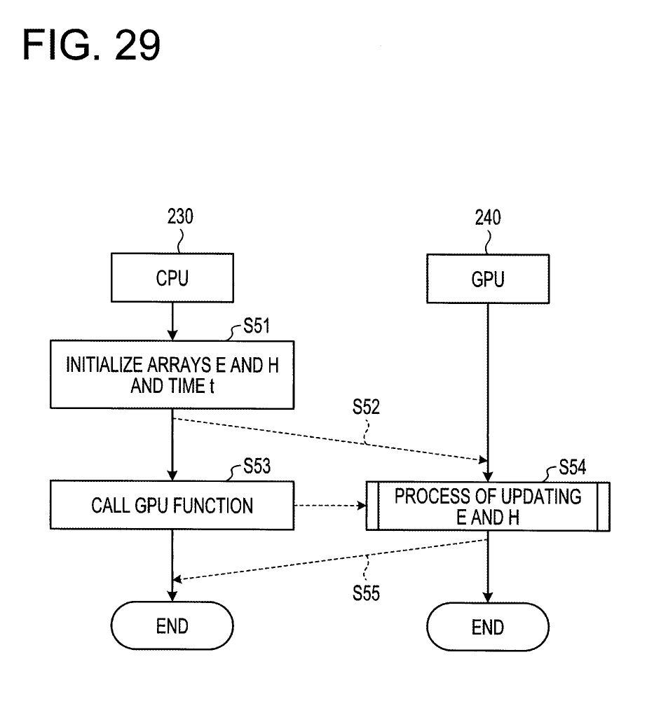

Subsequently, descriptions will be made on the operation of the information processing apparatus 200 according to the second embodiment. FIG. 29 is a flowchart illustrating an example of an updating process according to the second embodiment.

The setting circuit 231 initializes the arrays E and H corresponding to the respective cells of the electric field memory 121 and the magnetic field memory 122, and the time t (step S51). The setting circuit 231 outputs the initialized electric field data and magnetic field data to the GPU 240 (step S52). When outputting the electric field data and the magnetic field data to the GPU 240, the setting circuit 231 calls the GPU function and instructs the GPU 240 to execute the process of updating E and H (step S53).

The GPU 240 executes the process of updating E and H (step S54), and stores the electric field data and the magnetic field data after the process of updating E and H in the electric field memory 121 and the magnetic field memory 122. The GPU 240 notifies the setting circuit 231 of the completion of update (step S55).

Upon receiving the update completion notice from the GPU 240, the setting circuit 231 refers to the electric field memory 121 and the magnetic field memory 122, and displays the analysis result on, for example, the display circuit 111. As a result, the information processing apparatus 200 may reduce the number of memory accesses at the time of updating in the FDTD method.

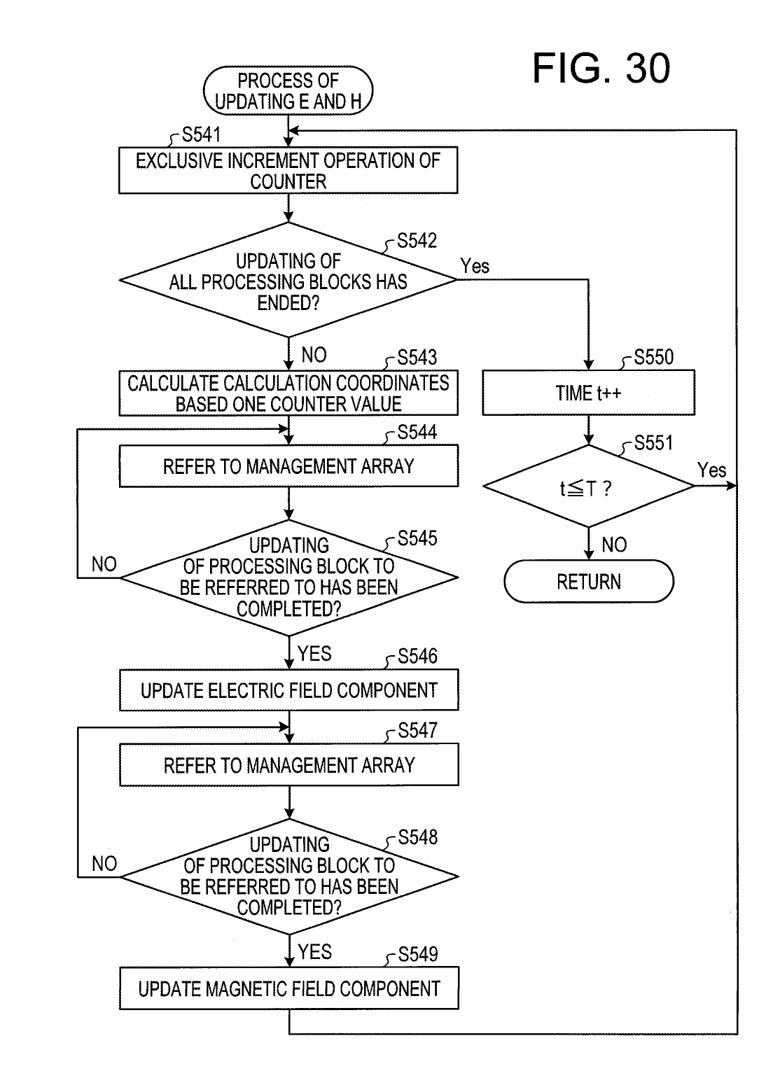

Here, the process of updating E and H in the GPU 240 will be described with reference to FIG. 30. FIG. 30 is a flowchart illustrating an example of the process of updating E and H.

The block 242 of the GPU 240 executes the process of updating E and H according to the call of the GPU function of the setting circuit 231. The block 242 executes the exclusive increment operation of the counter 241c (step S541).

The block 242 determines whether updating of all the processing blocks has ended (step S542). When it is determined that updating of all processing blocks has not ended (“No” in step S542), the block 242 calculates calculation coordinates based on the counter value of the counter 241c (step S543). The block 242 refers to the management array 241d (step S544) and determines whether updating of the processing block to be referred to when updating the electric field component of the processing block of interest has been completed (step S545). When it is determined that the updating of the processing block to be referred to has not been completed (“No” in step S545), the block 242 returns to step S544.

When it is determined that the updating of the processing block to be referred to has been completed (“Yes” in step S545), the block 242 updates the electric field component of the processing block of interest (step S546). When the updating of the electric field component of the processing block of interest has been completed, the block 242 refers to the management array 241d (step S547) and determines whether updating of the processing block to be referred to when updating the magnetic field component of the processing block of interest has been completed (step S548). When it is determined that the updating of the processing block to be referred to has not been completed (“No” in step S548), the block 242 returns to step S547.

When it is determined that the updating of the processing block to be referred to has been completed (“Yes” in step S548), the block 242 updates the magnetic field component of the processing block of interest (step S549) and returns to step S541.

In the meantime, when it is determined that the updating of all the processing blocks has ended in step S542 (“Yes” in step S542), the block 242 increments the time t (step S550). The block 242 determines whether the time t is equal to or less than the predetermined time T (step S551). When it is determined that the time t is equal to or less than the predetermined time T (“Yes” in step S551), the block 242 returns to step S541 to execute the process of updating E and H for the incremented time t. When it is determined that the time t is greater than the predetermined time T (“No” in step S551), the block 242 stores the electric field data and the magnetic field data after the updating process in the electric field memory 121 and the magnetic field memory 122 so as to end the process of updating E and H. In addition, the block 242 notifies the setting circuit 231 of the completion of update. As a result, the information processing apparatus 200 may reduce the number of memory accesses at the time of updating in the FDTD method.

In the second embodiment, the configuration of the GPU of NVIDIA Corporation has been described as an example, but the present disclosure is not limited to this. For example, the shared memory 242a may have a structure including a plurality of layers. In addition, like a GPU of AMD (registered trademark) Corporation, the shared memory 242a may have a configuration which includes a shader engine having plural sets of computer unit group and an L1 cache, and an L2 cache and a main memory accessible from each computer unit group. Further, the computer unit includes a high-speed memory called a local data share corresponding to the shared memory 242a.

As described above, the information processing apparatus 200 includes a block 242 corresponding to a plurality of update circuits, a counter for exclusive control of the cell to be updated (processing block), and a management array that manages the update state of the cell (processing block). Further, the information processing apparatus 200 determines a cell to be updated (processing block) based on the value of the counter, and stores the update result of the determined cell (processing block) in the management array. As a result, even when a parallel processing is performed, the information processing apparatus 200 may reduce the number of memory accesses at the time of updating in the FDTD method.

Further, in the information processing apparatus 200, the block 242 corresponding to the update circuit is the block 36 corresponding to the streaming processor 32, and the cache memory 21 is the shared memory 242a of the streaming processor 32. As a result, the information processing apparatus 200 may reduce the number of memory accesses at the time of updating in the FDTD method using the GPU.

In the information processing apparatus 200, the counter 241c and the management array 241d are arranged in the global memory 241 accessible from the plurality of blocks 242. As a result, the information processing apparatus 200 may appropriately allocate the updating process of the electromagnetic field component to each block 242.

Further, in the information processing apparatus 200, the block 242 corresponds to an area including a plurality of cells (processing block), and a plurality of threads perform a parallel processing within the area so as to update the cell. As a result, the information processing apparatus 200 may increase the utilization efficiency of the core 33 and increase the processing speed.

Further, each constituent element of each unit illustrated in the drawings is not necessarily physically configured as illustrated in the drawings. That is, the specific forms of distribution and integration of each unit are not limited to those illustrated in the drawings, but all or a part thereof may be distributed or integrated functionally or physically in arbitrary units according to various loads or usage situations. For example, the setting circuit 131 and the update circuit 132 may be integrated with each other. Also, each illustrated process is not limited to the above-described order, but may be performed simultaneously within a range that does not contradict the process contents, and may be executed with the reversed order.

Further, various processing functions performed by each device may be executed wholly or arbitrarily on a CPU (or a micro-computer such as an MPU or a micro controller unit (MCU)). It is also needless to say that all or a part of the various processing functions may be executed on a program analyzed and executed by a CPU (or a micro-computer such as an MPU or an MCU), or on a hardware by wired logic.

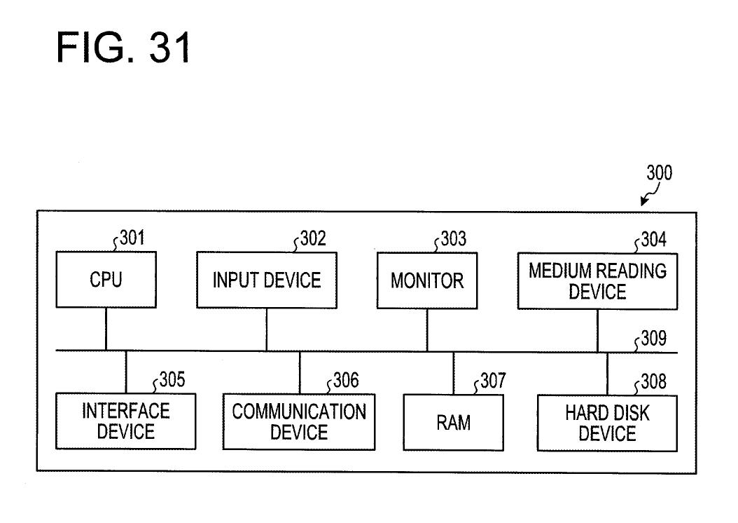

The various processes described in each of the above-described embodiments may be implemented by executing a program prepared in advance by a computer. Therefore, hereinafter, descriptions will be made on an example of a computer that executes a program having the same functions as those of the above-described embodiments. FIG. 31 is a diagram illustrating an example of a computer that executes an information processing program.

As illustrated in FIG. 31, the computer 300 includes a CPU 301 that executes various arithmetic processing, an input device 302 that receives data input, and a monitor 303. Further, the computer 300 includes a medium reading device 304 that reads a program from a storage medium, an interface device 305 that connects to various devices, and a communication device 306 that connects to another information processing device in a wired or wireless manner. Further, the computer 300 includes a RAM 307 that temporarily stores various types of information, and a hard disk device 308. In addition, each of the devices 301 to 308 is connected to the bus 309.

An information processing program having the same functions as the respective processing units of the setting circuit 131 and the update circuit 132 illustrated in FIG. 1 is stored in the hard disk device 308. Further, an information processing program having the same functions as the processing circuits of the setting circuit 231 illustrated in FIG. 15 and the block 242 of the GPU 240 is stored in the hard disk device 308. Further, various data which implements the electric field memory 121, the magnetic field memory 122, and the information processing program illustrated in FIG. 1 or 15 is stored in the hard disk drive 308.

The input device 302 receives the input of various information such as operation information from, for example, the administrator of the computer 300. The monitor 303 displays various screens such as a display screen with respect to, for example, the administrator of the computer 300. For example, a printing device is connected to the interface device 305. For example, the communication device 306 has the same function as the communication circuit 110 illustrated in FIG. 1 or 15, is connected to a network (not illustrated), and exchanges various information with other information processing devices.

The CPU 301 reads each program stored in the hard disk device 308, and develops and executes the program in the RAM 307, thereby performing various processes. In addition, these programs may cause the computer 300 to function as the setting circuit 131 and the update circuit 132 illustrated in FIG. 1. Alternatively, these programs may cause the computer 300 to function as the setting circuit 231 and the block 242 illustrated in FIG. 15.

The above-described information processing program is not necessarily stored in the hard disk device 308. For example, the computer 300 may read and execute a program stored in a storage medium readable by the computer 300. A storage medium readable by the computer 300 is, for example, a portable recording medium such as a CD-ROM, a digital versatile disc (DVD), a universal serial bus (USB) memory, a semiconductor memory such as a flash memory, or a hard disk drive. The information processing program may be stored in a device connected to, for example, a public line, the Internet, or a LAN, and the computer 300 may read and execute the information processing program from such a device.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to an illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. An information processing apparatus that performs a process of an N-dimensional FDTD method, the information processing apparatus comprising:
a memory; and
a processor coupled to the memory and configured to:
update a cell in a +1 direction of a predetermined coordinate of an N-dimension,
store an updated value in a cache memory, and
after storing the updated value, update the cell of the predetermined coordinate using the updated value stored in the cache memory.

2. The information processing apparatus according to claim 1, wherein the processor is configured to:
update an electric field component of the cell of the predetermined coordinate,
update a magnetic field component of the cell of the predetermined coordinate using an electric field component after updating the cell of the predetermined coordinate and the cell in the +1 direction of the predetermined coordinate and a magnetic field component before updating the cell of the predetermined coordinate.

3. The information processing apparatus according to claim 1,
wherein the processor is configured to update the cell in an order from a cell whose coordinate value in an area to be analyzed is a maximum value to a cell whose coordinate value is a minimum value.

4. The information processing apparatus according to claim 1, further comprising:
a plurality of the processors;
a counter that performs an exclusive control of the cell to be updated; and
a management array that manages an update state of the cell,
wherein each of the plurality of the processors is configured to:
determine the cell to be updated based on a value of the counter, and
store an update result of a determined cell in the management array.

5. The information processing apparatus according to claim 4, wherein
each of the plurality of the processors is a block corresponding to a streaming processor, and
the cache memory is a shared memory of the streaming processor.

6. The information processing apparatus according to claim 5,
wherein the counter and the management array are arranged in a global memory accessible from a plurality of blocks.

7. The information processing apparatus according to claim 5, wherein
the block corresponds to an area including a plurality of cells, and
the cell is updated by performing a parallel process by a plurality of threads in the area.

8. An information processing method executed by a processor included in an information processing apparatus that performs a process of an N-dimensional FDTD method, the method comprising:
updating a cell in a +1 direction of a predetermined coordinate of an N-dimension;
storing an updated value in a cache memory; and
after storing the updated value, updating the cell of the predetermined coordinate using the updated value stored in the cache memory.

9. A non-transitory computer-readable recording medium storing a program that causes a processor included in an information processing apparatus to execute a process of an N-dimensional FDTD method, the process comprising:
updating a cell in a +1 direction of a predetermined coordinate of an N-dimension;
storing an updated value in a cache memory; and
after storing the updated value, updating the cell of the predetermined coordinate using the updated value stored in the cache memory.
